(19) United States
(12) Patent Application Publication
(10) Pub. No.: US 2006/0228912 A1
(43) Pub. Date: Oct. 12, 2006

(54) Orthogonal backplane connector

(75) Inventors: Danny L.C. Morlion, Ghent (BE); Steven E. Minich, York, PA (US); Stephen B. Smith, Mechanicsburg, PA (US)

Correspondence Address: WOODCOCK WASHBURN, LLP, ONE LIBERTY PLACE - 46TH FLOOR, PHILADELPHIA, PA, 19103, US

(73) Assignee: FCI Americas Technology, Inc., Reno, NV (US)

(21) Appl. No.: 11/388,549

(22) Filed: Mar. 24, 2006

Related U.S. Application Data
(60) Provisional application No. 60/669,103, filed on Apr. 7, 2005.
(60) Provisional application No. 60/718,535, filed on Sep. 19, 2005.

(51) Int. Cl. H05K 1/00

(52) U.S. Cl. 439/65

(57) ABSTRACT

An orthogonal backplane connector systems having midplane footprints that provide for continuity of impedance and signal integrity through the midplane and allow for the same connector to be coupled to either side of the midplane. This design creates an orthogonal interconnect without taking up unnecessary PCB real estate. The midplane circuit board may include a first differential signal pair of electrically conductive vias disposed in a first direction, and a second differential signal pair of electrically conductive vias disposed in a second direction that is generally orthogonal to the first direction. The first and second differential signal pair of electrically conductive vias are electrically connected through the midplane circuit board. Each pair may be associated with and be located in between ground vias. A ground via that is large relative to the signal vias may be provided. The second signal vias may comprise a shared signal via, receiving a contact from respective connectors connected to each side of the midplane circuit board. The second signal vias may comprise partial signal vias, extending from one or more sides partially into the midplane circuit board. The signal pairs may be offset from a via array centerline formed by the ground vias to correspond with mating ends of signal contacts of an electrical connector that likewise jog away from a centerline of a respective contact column of the connector.

### RELATED APPLICATIONS

The subject matter disclosed herein is related to the subject matter disclosed in provisional U.S. Patent Application having Ser. No. 60/669,103, filed Apr. 7, 2005, entitled “Orthogonal Backplane Connector,” and provisional U.S. Patent Application having Ser. No. 60/718,535, filed Sep. 19, 2005, entitled “Orthogonal Backplane Connector”; both of which are assigned to the assignee of the present application and hereby incorporated herein by reference in their entirety.

### FIELD OF THE INVENTION

Generally, the invention relates to orthogonal backplane connectors. More particularly, the invention relates to orthogonal backplane connector systems having midplane footprints that provide for continuity of impedance and signal integrity through the midplane and allow for the same connector to be coupled to either side of the midplane.

### BACKGROUND OF THE INVENTION

An electronic system, such as a computer, for example, may include components mounted on printed circuit boards, such as daughtercards, backplane boards, motherboards, and the like, that are interconnected to transfer power and data signals throughout the system. A typical connector assembly may include a respective backplane connector attached to each of a motherboard and daughtercard, for example. The backplane connectors may be joined to one another to electrically connect the motherboard and the daughtercard. The daughtercard may be aligned orthogonally to the motherboard. In orthogonal arrangements, the daughtercards may be arranged horizontally on one side of a substrate, such as a midplane, for example, and arranged vertically on the other side of the substrate.

In an orthogonal connector system, there is a need to electrically connect a daughtercard positioned on one side or surface of a midplane circuit board to a corresponding daughtercard positioned on an opposite side or surface of the midplane. In the approach disclosed in U.S. Pat. No. 6,608,762, for example, pins from two contact modules extend into matching holes in a midplane. One set of pins extends into the holes from one side of the midplane, and the other set of pins extends into the same set of holes from the other side of the midplane. Many layers are shown in the circuit board. In another approach, disclosed in U.S. Pat. No. 6,392,142, only one pin is inserted into each hole in the midplane. Each of the single pins extends beyond the first and second surfaces of the midplane, and the pins receive plastic headers. U.S. Pat. No. 6,392,142 discloses that the daughtercards perform functions of the backplane, which helps to decrease the number of wiring layers in the backplane. In U.S. Pat. No. 4,232,924, a conductive trace extends between a contact of a first connector and a contact of a second connector that is positioned on an opposite side of the substrate. Each of the patents listed above is incorporated by reference in its entirety.

### SUMMARY OF THE INVENTION

In general, one aspect of the present invention is to use two substantially identical connectors, each with straight mounting contacts, to create an orthogonal interconnect without taking up unnecessary PCB real estate wherein each side of the midplane has the same footprint.

A midplane circuit board for an orthogonal connector system may include a first differential signal pair of electrically conductive vias disposed in a first direction, the first differential signal pair comprising a first signal via and a second signal via, and a second differential signal pair of electrically conductive vias disposed in a second direction that is generally orthogonal to the first direction, the second differential signal pair comprising the second signal via and a third signal via. Each pair may be associated with and be located in between ground vias. The signal pairs may be offset from a via array centerline formed by the ground vias to correspond with mating ends of signal contacts of an electrical connector that likewise jog away from a centerline of a respective contact column of the connector. The second signal via may be a shared signal via, receiving a contact from respective connectors connected to each side of the midplane circuit board. At least one of the first and .the third vias may be backdrilled and may be electrically connected midway between a front and a back face of the midplane. Alternatively, the first and third vias may be electrically connected in the vicinity of at least one surface of the midplane. The first differential signal pair of electrically conductive vias may be disposed to receive a first differential signal pair of electrical contacts from a first electrical connector mounted to a first side of the midplane circuit board. The second differential signal pair of electrically conductive vias may be disposed to receive a second differential signal pair of electrical contacts from a second electrical connector mounted to a second side of the midplane circuit board. The first and second connectors may have an identical pin layout. The first and second connectors may be interchangeable with one another.

An electrical connector according to the invention may include an electrical contact that extends at least partially through a dielectric material, and a housing having a receptacle part and a header part. The header part may have an elongated post that extends beyond the terminal end of the contact. The receptacle part may define a complementary recess for receiving the elongated post.

The electrical connector may include adjacent columns of electrical contacts, wherein the recess is defined between the adjacent columns. The electrical connector may include adjacent columns of electrical contacts, wherein the post is disposed between the adjacent columns. The post and recess may cooperate to guide the connector into mating engagement with a circuit board. The post and recess may cooperate to guide the terminal end of the contact into a complementary receiving aperture on the circuit board. The post may be made of an electrically insulating material. The housing may define an opening disposed to allow air to flow adjacent to the contact. The electrical connector may include adjacent columns of electrical contacts, wherein the opening is disposed to allow air to flow between the adjacent columns. The opening may be arch-shaped. The header part may include one or more alignment cavities disposed such that the connector may be mated in only one orientation. The header part may include one or more polarization pegs that extend therefrom. The polarization pegs may be adapted to be received in complementary holes in a circuit board. The pegs and holes may be disposed such that the header part may be applied onto the midplane in only one orientation.

A midplane circuit board for an orthogonal connector system may include a first differential signal pair of electrically conductive vias disposed in a first direction, the first differential signal pair comprising a first signal via and a second signal via, and a second differential signal pair of electrically conductive vias disposed in a second direction that is generally orthogonal to the first direction, the second differential signal pair comprising the second signal via and a third signal via. The second signal via may be a shared via. The midplane additionally may include a signal via offset from the respective linear array of vias, wherein the offset via is connected to an elongated pad disposed for electrical connection with surface-mount contacts of respective IMLAs. The elongated pads may be connected at a front and back face of the midplane to the same via.

A daughtercard footprint may include a first linear array of vias comprising two signal vias, each surrounded by an anti-pad, and a ground via. A second linear array of vias may include two signal vias, each surrounded by an anti-pad, forming a linear array with a ground via. The first and second linear arrays may be parallel. Separating the first and second linear arrays may be three pairs of electrically conductive traces. Each trace of each pair of traces may be separated a distance that is less than a distance between each pair of traces.

A midplane circuit board for an orthogonal connector system may include a first differential signal pair of electrically conductive vias disposed in a first direction, the first differential signal pair comprising a first signal via and a second signal via, and a second differential signal pair of electrically conductive vias disposed in a second direction that is generally orthogonal to the first direction, the second differential signal pair comprising a third signal via and a fourth signal via. The first signal via may be electrically connected to the third signal via in the vicinity of at least one surface of the midplane. The first signal via and the third signal via may be the same via. The second signal via may be electrically connected to the fourth signal via in the vicinity of at least one surface of the midplane. The first signal via and the third signal via may be back drilled. Alternatively, the first, second, third, and fourth signal vias may be backdrilled and respective vias may be electrically connected at a midpoint between a back and a front face of the midplane. The first differential signal pair of electrically conductive vias may be disposed to receive a first differential signal pair of electrical contacts from a first electrical connector mounted to a first side of the midplane circuit board. The second differential signal pair of electrically conductive vias may be disposed to receive a second differential signal pair of electrical contacts from a second electrical connector mounted to a second side of the midplane circuit board. The first and second connectors may have an identical pin layout. The first and second connectors may be interchangeable with one another.

The midplane circuit board may include a first ground via disposed adjacent to the first differential signal pair of electrically conductive vias along the first direction, and a second ground via disposed adjacent to the second differential signal pair of electrically conductive vias along the second direction. The first ground via may be electrically connected to the second ground via. The midplane circuit board may include a relatively large ground via disposed adjacent to at least one of the differential signal pairs. The relatively large ground via may be electrically connected to at least one of the first and second ground vias. The midplane circuit board may include a relatively small signal via disposed adjacent to at least one of the first and second signal vias. The relatively small signal via may be electrically connected to at least one of the first and second signal vias.

A midplane circuit board for an orthogonal connector system may include a first signal via disposed within a first column of electrically conductive vias, and a second signal via disposed within a second column of electrically conductive vias. The first column may be disposed along a first direction and the second column may be disposed along a second direction that is generally orthogonal to the first direction. The first signal via may be electrically connected to the second signal via.

A midplane circuit board for an orthogonal connector system may include a plurality of signal vias arranged in orthogonal columns to receive a first column of electrical contacts from a first electrical connector mounted to a first side of the midplane circuit board and a second column of electrical contacts from a second electrical connector mounted to a second side of the midplane circuit board. Each of the vias may carry at least one of signal and ground through the midplane between the first and second electrical connectors.

A midplane circuit board may include a circuit board defining a plurality of ground vias arranged in a quadrilateral, i.e. four-sided pattern. The ground vias may be electrically interconnected to one another by an electrically conductive bridge. The midplane circuit board may also include a first pair of signal vias and a second pair of signal vias circumscribed at least in part by the electrically conductive bridge. The first pair of signal vias may be electrically connected to one another by a second electrically conductive bridge. The midplane circuit board may include an enlarged ground via electrically connected to the electrically conductive bridge.

An electrical connector for use with orthogonal daughtercards and a midplane may include an insulative header having a mating face and a plurality of electrical contacts arrayed into a matrix of rows and columns such that the contact array has a square envelope when viewed from a mating end of the connector. The number of contacts per column may be greater than the number of contacts per row. The connector may include five columns of contacts. Each column may include 15 contacts. The connector may include six columns of contacts. Each column may include 18 contacts.

### BRIEF DESCRIPTION OF THE DRAWINGS

FIG. 1A depicts a pair of electrical connectors mated orthogonally to one another;

FIG. 1B depicts the electrical connectors shown in FIG. 1A, without housings;

FIGS. 2A and 2B depict orthogonal receptacle connector assemblies coupled to a midplane;

FIGS. 3A and 3B depict orthogonal header connector assemblies coupled to circuit boards;

FIG. 4 depicts a perspective view of an example prior art circuit board via arrangement;

FIG. 5A depicts a perspective view of a midplane via arrangement according to the invention;

FIGS. 5B-5C depict, respectively, graphical representations of impedance profile and insertion loss associated with the via arrangement of FIG. 5A;

FIGS. 5D-5G depict graphical representations of eye-patterns at different bit rates associated with the via arrangement of FIG. 5A;

FIGS. 6A-6D depict associated example midplane footprints, example ground and signal assignments associated with the footprints, and a midplane via arrangement associated with the footprints;

FIG. 7 depicts an alternative example of a midplane via arrangement, according to the invention;

FIG. 8 depicts an alternative example of a midplane via arrangement, according to the invention;

FIG. 9 depicts an alternative example of a midplane via arrangement, according to the invention;

FIGS. 10A-10D depict associated alternative example midplane footprints, example ground and signal assignments associated with the footprints, and an example midplane via arrangement associated with the footprints;

FIGS. 11A-11D depict associated alternative example midplane footprints, example ground and signal assignments associated with the footprints, and an example midplane via arrangement associated with the footprints;

FIG. 12 depicts an alternative example of a midplane via arrangement, according to the invention;

FIG. 13 depicts an alternative example of a midplane via arrangement, according to the invention;

FIG. 14A depicts an alternative midplane footprint, according to the invention;

FIG. 14B depicts a transparent view of the midplane footprint of FIG. 14A;

FIG. 14C depicts an IMLA connected to a midplane comprising the footprint depicted in FIGS. 14A and 14B;

FIGS. 15A and 15B depict a midplane having a plurality of IMLAs assembled thereto;

FIGS. 16A and 16B depict a midplane having a plurality of receptacle assemblies applied thereto;

FIGS. 17A and 17B depict an alternative example of a midplane footprint;

FIGS. 18A and 18B depicts example ground and signal assignments associated with an alternative midplane footprint and an example midplane via arrangement associated with the footprint;

FIGS. 18C and 18D depicts example ground and signal assignments associated with an alternative midplane footprint and an example midplane via arrangement associated with the footprint;

FIG. 19 depicts a diagram of an example contact arrangement for an electrical connector adapted to be orthogonally connected to a similarly-arranged connector;

FIG. 20 depicts a portion of an alternative example of a daughtercard footprint;

FIG. 21 depicts a portion of an alternative example of a daughtercard footprint;

FIGS. 22A-22D depict example connector polarization features;

FIGS. 23A and 23B depict an alternative orthogonal connector assembly;

FIG. 24 depicts a transparent view of the orthogonal connector assembly shown in FIGS. 23A and 23B;

FIGS. 25A-25C depict an alternative example of an orthogonal header assembly;

FIGS. 26A and 26B depict an alternative example of an orthogonal receptacle assembly;

FIGS. 27A and 27B depict an alternative example of an orthogonal connector assembly; and

FIG. 28 depicts transparent view of the orthogonal connector assembly shown in FIGS. 27A and 27B.

### DETAILED DESCRIPTION OF ILLUSTRATIVE EMBODIMENTS

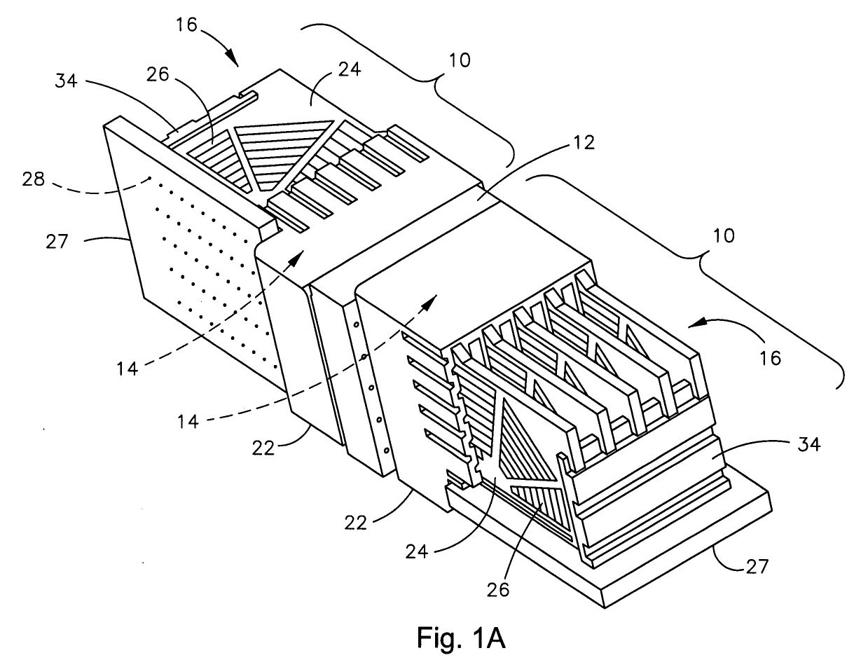

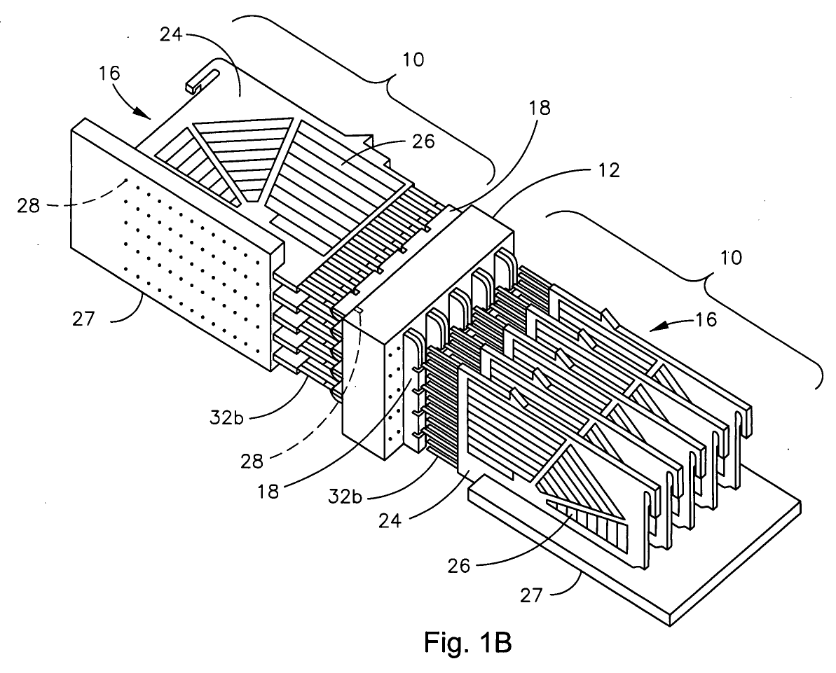

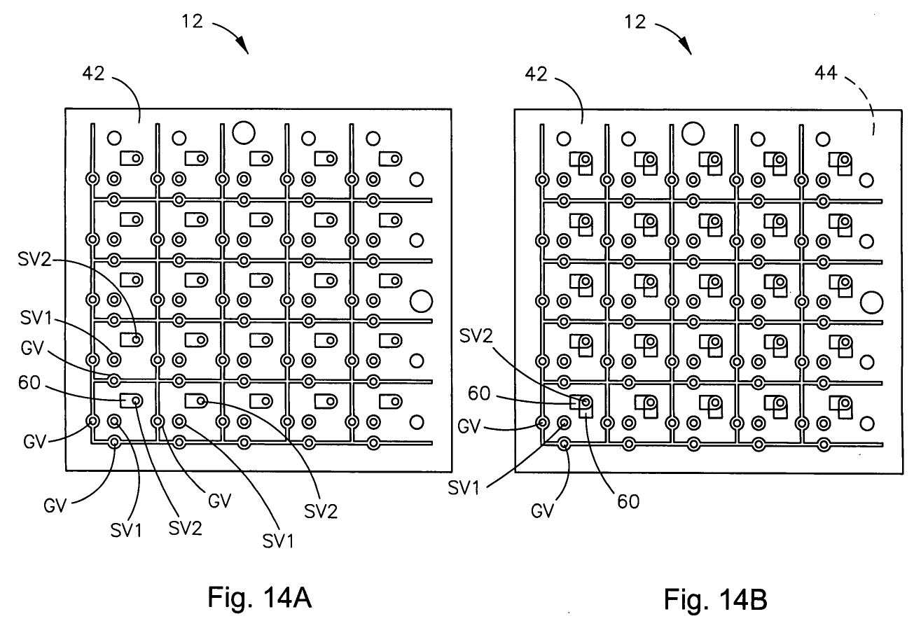

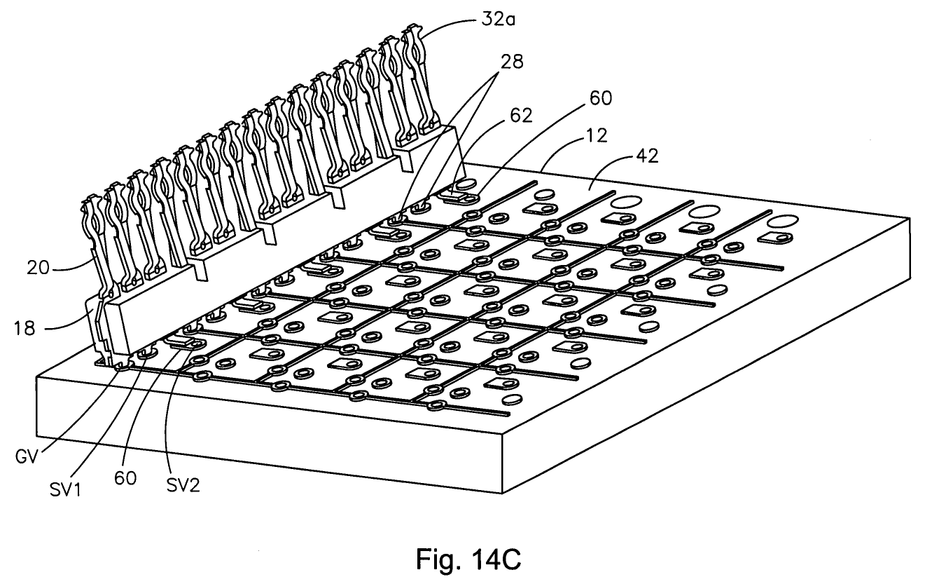

FIGS. 1A and 1B show two electrical connector assemblies 10 attached to a midplane 12. The electrical connector assemblies 10 each comprise a midplane connector 14 and a right angle connector 16. Each midplane connector 14 has a midplane IMLA 18 that carries midplane contacts 20 (FIG. 14C) that are electrically connected to a midplane 12 via press-fit, surface mount, BGA, or other suitable types of electrical terminations. In FIG. 1A, the right angle connector housing 22 receives right angle IMLAs 24. Right angle IMLAs 24 each carry right angle contacts 26 that are attached to daughtercards 27 via press-fit, surface mount, BGA, or other suitable types of connection tails 28.

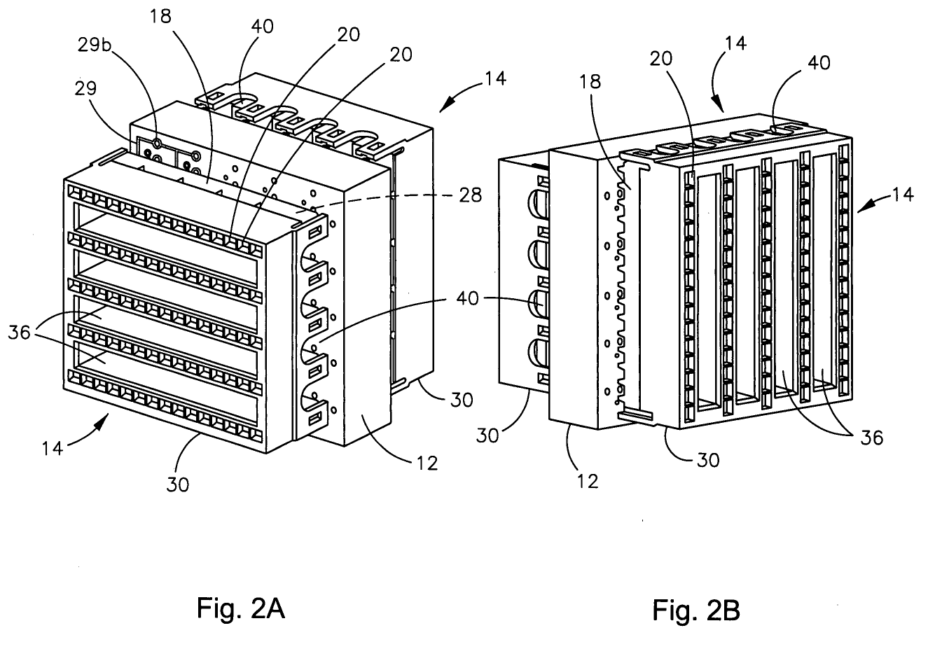

FIG. 1B is the same as FIG. 1A, except that right angle connector housing 22, the midplane contacts 20 (FIG. 14C), and a midplane connector housing 30 (FIGS. 2A and 2B) are removed for clarity. The right angle contacts 26 can terminate at a mating end 32b with a blade as shown or cantilevered female contact beams. Simarily, the midplane contacts 20 (FIG. 14C) can terminate at a mating end 32a with cantilevered female contact beams as shown in FIG. 14C or a blade.

Each midplane IMLA 18 and right angle IMLA 24 may include midplane contacts 20 or right angle contacts 26 that extend through a dielectric material 20, such as air or plastic, for example. Examples of preferred connectors are disclosed in U.S. Pat. Nos. 6,988,902 and 6,981,883, both of which are herein incorporated by reference in their entirety.

As best shown in FIGS. 1B and 14C, the contacts 20, 26 in each respective midplane IMLA 18 or right angle IMLA 24 may form respective linear contact arrays. As shown, the linear contact arrays may be arranged as contact columns, though it should be understood that the linear contact arrays could be arranged as contact rows. Also, though the connectors 16 are depicted with seventy-five contacts (i.e., five right angle IMLAs 24 with fifteen contacts 26 per IMLA), it should be understood that a midplane IMLA 18 or a right angle IMLA 24 may include any desired number of contacts 26 and a connector 14, 16 may include any number of IMLAs 18, 24.

The midplane contacts 20 and the right angle contacts 26 may also be tightly electrically edge-coupled within each midplane IMLA 18 or right angle IMLA 24, i.e., aligned edge-to-edge with or without a corresponding ground or reference plane and spaced closely enough, i.e. about 0.3-0.4 mm in air and about 0.4-0.8 mm in plastic, to one another such that they produce electrical fields that limit crosstalk between active contacts in adjacent rows to six percent or less at rise times of about 200-35 picoseconds. Edge-coupling of contacts is disclosed, for example, in U.S. patent application Ser. No. 10/294,966, the disclosure of which is incorporated herein by reference in its entirety.

In an example embodiment, an IMLA-may be used, without modification, for single-ended signaling, differential signaling, or a combination of single-ended signaling and differential signaling. Examples of such IMLAs are disclosed and described in U.S. Patent Application Publication No. 2004-0997112, entitled “Electrical Connectors Having Contacts That May Be Selectively Designated As Either Signal Or Ground Contacts” which is hereby incorporated herein by reference in its entirety.

Though the assemblies connectors 10 depicted in FIGS. 1A and 1B are right-angle connectors with daughtercards orthogonal to the midplane 12, it should be understood that the connectors could be any style connector, such as a mezzanine connector, for example.

As shown in FIG. 1A, the right angle connector 16 may include an IMLA retention member 34. Example embodiments of such an IMLA retention member are described in U.S. patent application Ser. No. 10/842,397, filed on May 10, 2004, entitled “Retention Member For Connector System.” The disclosure of U.S. patent application Ser. No. 10/842,397 is hereby incorporated herein by reference in its entirety.

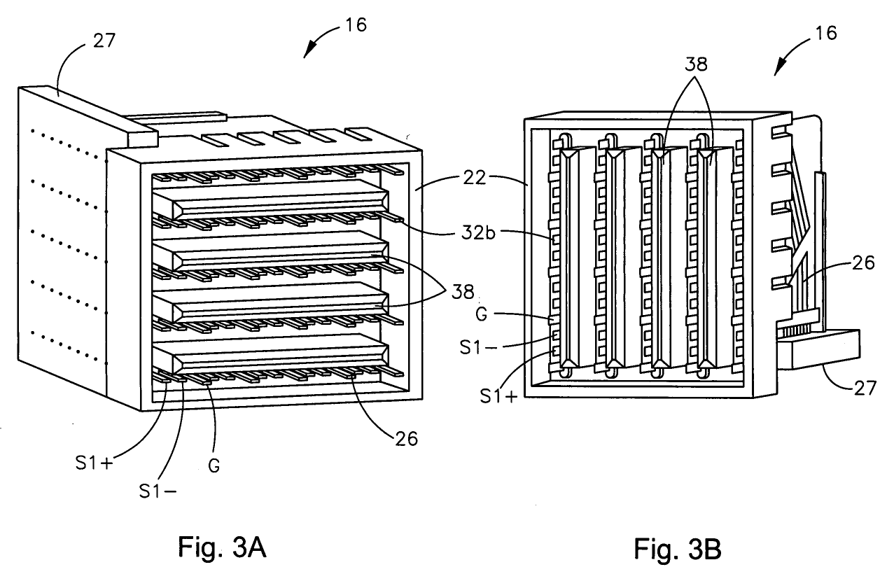

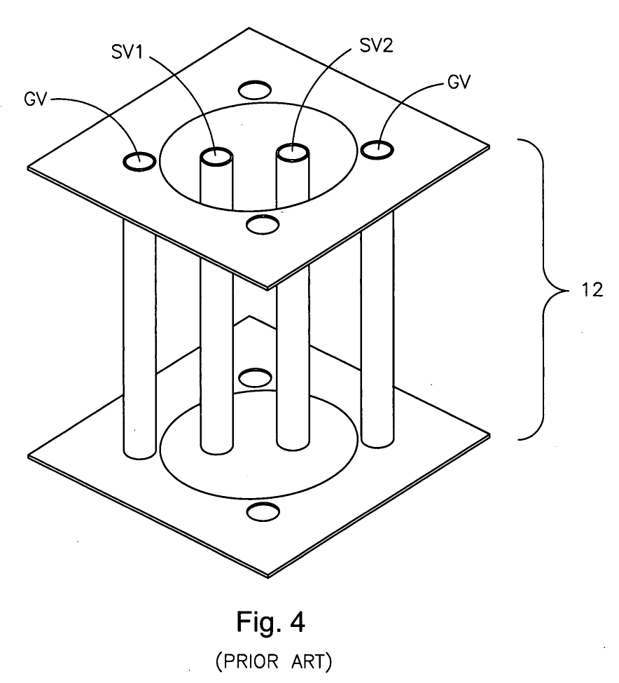

As shown in FIGS. 2A and 2B, each midplane connector 14 comprises midplane IMLAs 18 and midplane contacts 20. Midplane contacts 20 are connected to midplane 12 by connector tails 28. FIGS. 2A and 2B depict opposing midplane connectors 14, including midplane connector housings 30. The midplane connector housings 30 or the right angle connector housing 22 may define one or more recesses 36 for receiving respective elongated posts 38 (FIGS. 3A and 3B) defined by the right angle connector housing 22 or the midplane connector housing 30. For cooling purposes, the midplane connector housing 30 may also include one or more openings 40 disposed to allow air to circulate between adjacent midplane IMLAs 18. Such openings 40 may be arch-shaped, as shown, and may be disposed between adjacent midplane IMLAs 18.

As shown in FIGS. 3A and 3B, the elongated posts 38 mentioned above may serve as guide posts and pin protectors for the mating ends 32b of right angle contacts 26 or the mating ends 32a of the midplane contacts 20 in a reverse contact arrangement. The posts 38 may extend beyond the mating ends 32b of the right angle contacts 26 and, consequently, protect the contacts 26 from bending or other such damage during shipping, handling and mating. Further, to minimize incidence of bending during insertion, the posts 38 and recesses 36 (FIGS. 2A and 2B) cooperate to guide the midplane connector 14 and the right angle connector 16 into mating engagement. The elongated posts 38 may be made of an electrically insulating material, such as plastic, for example. In an example embodiment, columns of contacts 20, 26 may be spaced about 4.2 mm apart.

In an example embodiment shown in FIGS. 3A and 3B, the right angle contacts 26 in a column may be arranged in the well-known signal-signal-ground arrangement. A similar arrangement is on the midplane IMLA 18 (FIGS. 2A, 2B, 14C) as well. Accordingly, a linear array of fifteen contacts may yield one to five or more differential signal pairs, with a ground contact G between each pair of contacts that form a differential signal pair S1+, S1−. Mating end 32b of ground contact G may extend beyond the mating ends 32b of the signal contacts S1+, S1− so that the ground contact G mates before any of the signal contacts S1+, S1−. The connector assemblies 10 may be devoid of internal/external shields, there are preferably no shields between the midplane IMLAs 18 or the right angle IMLAs 24, and the IMLAs 18, 24 may include any combination of single-ended signal conductors and differential signal pairs.

As best seen in FIG. 3B, though the number of contacts right angle contacts 26 per row may, in general, be fewer than the number of contacts per column, the contacts 26 may be arrayed into a matrix of rows and columns such that the resulting contact array has a four-sided, i.e., square envelope when viewed from a mating end of the right angle connector 16.

A midplane 12 may also include one or more ground conducting paths 29 (FIG. 2A). The ground conducting paths 29 may also include an electrically conductive via 29b that extends through the circuit board 12.

FIG. 4 depicts a perspective view of an example prior art circuit board via arrangement. The circuit board via arrangement may include two ground vias GV for electrical connection to respective ground contacts of an electrical connector and two signal vias SV1, SV2 for electrical connection to respective signal contacts S1+, S1− of the midplane connector 14. Thus, the via arrangement is in a ground-signal-signal-ground orientation.

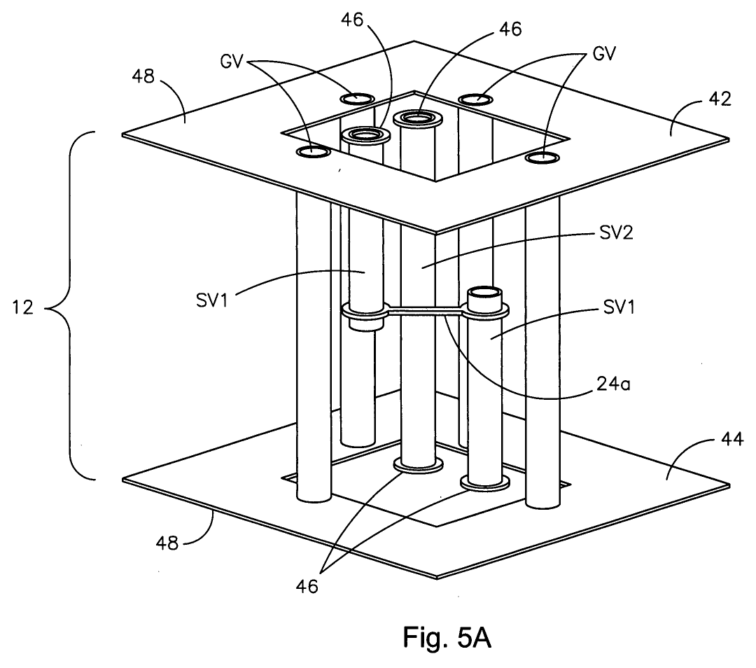

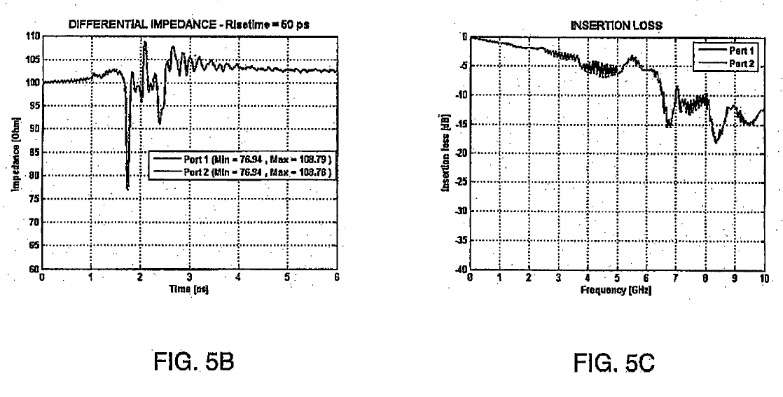

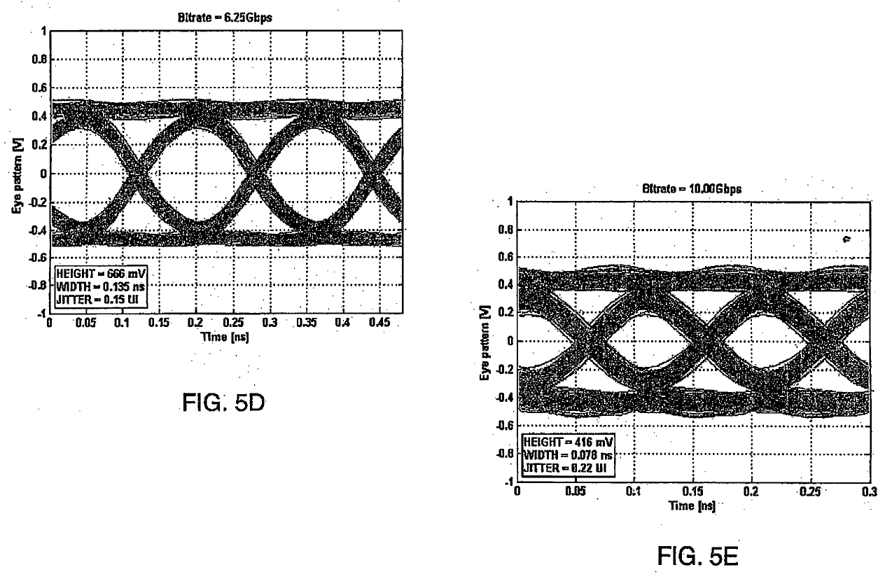

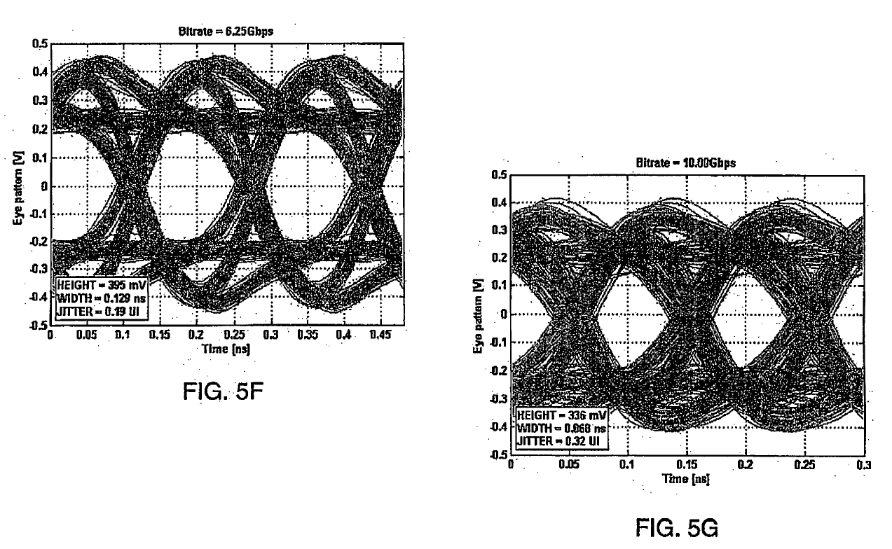

As shown in FIG. 5A, midplane 12 may include a front face 42 and a back face 44. One or more differential signaling paths SV1, SV2, single-ended signaling paths, or a combination of differential signaling paths and single-ended signaling paths are defined by signal vias SV1, SV2 and ground vias GV that extend into the midplane 12. Vias, such as signal vias SV1 and SV2, may be electrically connected by an electrically conductive trace 24a and may terminate with a conductive pad 46.

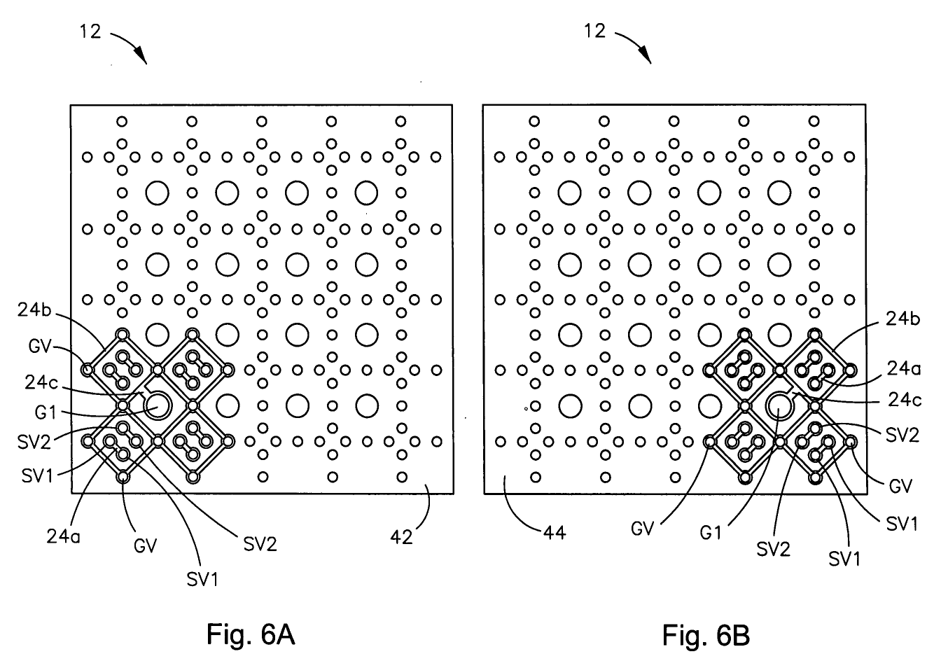

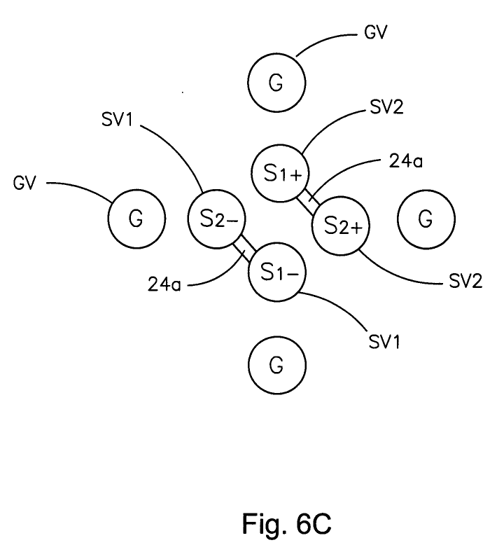

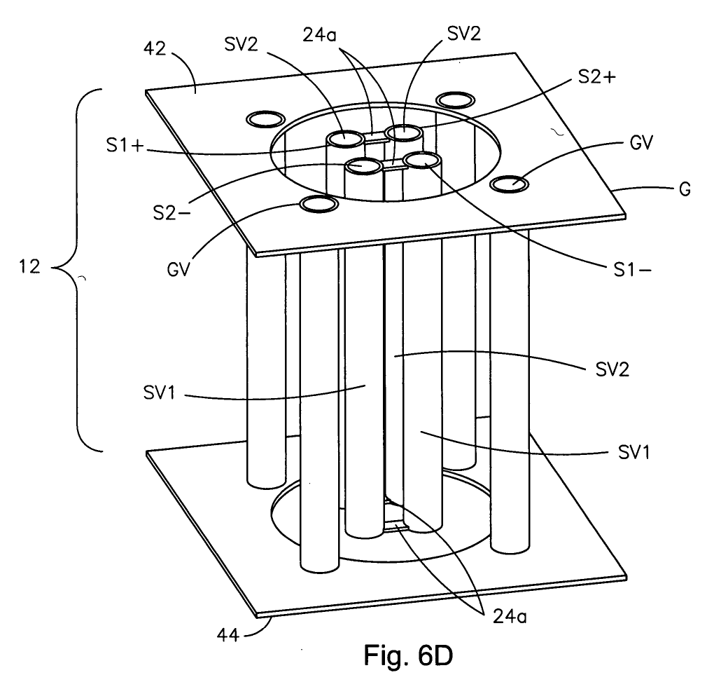

As shown in FIG. 5A, ground vias GV may be interconnected by a ground plane 48 or by electrically conductive traces 24b (FIG. 6A). Thus, ground vias GV may track through the midplane 12. Preferably, the ground vias GV have diameters of about 0.6 mm drill hole (i.e., before plating) or about 0.5 mm finished hole (i.e., after plating), though it is anticipated that the ground vias GV may have diameters in the range of about 0.4 mm to about 0.8 mm.

The via arrangement shown in FIG. 5A includes a shared via SV2. That is, via SV2 is disposed to receive a signal contact S1+ of a first midplane IMLA 18 on a front face 42 of the midplane 12 and may be the same via SV2 arranged to receive a signal contact S2+ of a second midplane IMLA 18 on a back face 44 of the midplane 12. Thus, the shared signal via SV2 may extend from the front face 42, through the midplane 12, to the back face 44 of the midplane 12.

Non-shared signal vias SV1 may extend from respective faces 42, 44 of the midplane 12 to approximately midway into the midplane 12. These non-shared signal vias SV1 may be electrically connected together by an electrically conductive trace 24a. That is, while other ground and signal vias GV, SV2 in the midplane 12 extend from the front face 42 to the back face 44 of the midplane 12, non-shared signal vias SV1 may extend only partially into the midplane 12 from the front face 42 and back face 44. When creating such a via arrangement, the unshared signal vias SV1 may extend from the front face 42 to the back face 44 of the midplane 12, as with the shared signal via SV2 and the ground vias GV. Thus, the unshared signal vias SV1 may have an unused but plated end portion on the side of the midplane 12 that does not receive a contact of an electrical connector. Such unused end portions are hereinafter referred to as “stubs.” Plating from such stubs may be removed by backdrilling or other suitable methods so that the stubs are not disposed to electrically connect to a contact of an electrical connector. Removal of plating material from the stubs may improve the electrical performance of the midplane and result in a via arrangement shown in FIG. 5A.

FIG. 5B is a graphical representation of exemplary differential impedance associated with the via arrangement depicted in FIG. 5A.

FIG. 5C is a graphical representation of insertion loss associated with the via arrangement depicted in FIG. 5A.

FIGS. 5D-5G depict graphical representations of eye-patterns at different bit rates associated with the footprint depicted in FIG. 5A.

FIGS. 6A and 6B depict a front side 42 and a back side 44, respectively, of an example midplane 12 footprint, according to one embodiment of the invention. FIG. 6C depicts example ground and signal assignments associated with the footprints of FIGS. 6A and 6B. FIG. 6D depicts a perspective view of an example midplane via arrangement associated with the footprints of FIGS. 6A and 6B. With regard to FIGS. 6A and 6B, linear arrays of vias SV, GV may be disposed (vertically, as shown) to receive columns of electrical contacts from a midplane IMLA located on a first side 42 of the midplane 12. Linear arrays of vias SV, GV may be disposed (horizontally, as shown) to receive columns .of electrical contacts from a midplane IMLA that is disposed orthogonally to the midplane on a second side 44 of the midplane 12. The vias in each linear array may be arranged in signal-signal-ground arrangement to correspond to a signal-signal-ground arrangement of the connector contacts.

As shown in FIGS. 6A and 6B, the ground vias GV may be interconnected by electrically conductive traces 24b. Thus, grounds may track through the midplane 12. Preferably, the ground vias GV have diameters of about 0.6 mm drill hole (i.e., before plating) or about 0.5 mm finished hole (i.e., after plating), though it is anticipated that the ground vias may have diameters in the range of about 0.4 mm to about 0.8 mm. Optional large ground vias G1 may be provided between signal vias SV1, SV2 in order to reduce crosstalk between pairs S1+, S1− in the connector footprint. A large ground via G1 may be interconnected by a trace 24c to the other ground vias GV. The large ground vias G1 may have diameters of about 1 mm, for example, and it is anticipated that the large ground vias G1 may have plated diameters in the range of about 0.5 mm to about 1.5 mm.

To track signal pairs through the midplane 12, signal vias SV1, SV1 may be interconnected by electrically conductive traces 24a. As shown in FIG. 6C, a first linear array of signal/ground vias SV1, SV2, GV may be disposed to receive columns of electrical contacts 20 from a first midplane connector 14 (FIGS. 2A and 2B). A second linear array of signal/ground vias SV1, SV2, GV may be disposed to receive columns of electrical contacts 20 from a second midplane connector 14 that is disposed orthogonally to the first midplane connector 14. As shown, horizontal signal vias SV1, SV2 may correspond to a first differential signal pair S1+, S1− in a first midplane connector 14. Similarly, vertical signal vias SV1, SV2 may correspond to a second differential signal pair S2+, S2− in a second midplane connector 14. A first trace 24a may electrically connect signal vias SV1, SV1 and SV2, SV2. Additionally, as may best be seen in FIG. 6D, the signal vias SV1, SV1 and SV2, SV2 may be parallel one another. Likewise, a second trace 24a may electrically connect signal vias SV1, SV1 and SV2, SV2 The signal vias SV1, SV1 may also be parallel to one another, and may also be parallel to the signal vias SV2, SV2. Thus, the signal pairs S1+, S1− and S2+, S2− continue to track through the midplane 12.

To optimize impedance through the midplane, there need not be a connector ground plane (i.e., a ground plane that extends throughout the connector footprint). Ground vias GV may be connected to ground G in both circuit boards through the connectors 14 (FIGS. 2A and 2B). An extra row of ground vias GV may be added to the footprint along one or more sides. The extra rows need not have press-fit tails inserted, though press-fit tails may be inserted where multiple connectors are stacked end-to-end. It should be understood that, though only two pairs are shown with traces, the pattern of traces may repeat for any or all segments of the midplane footprint.

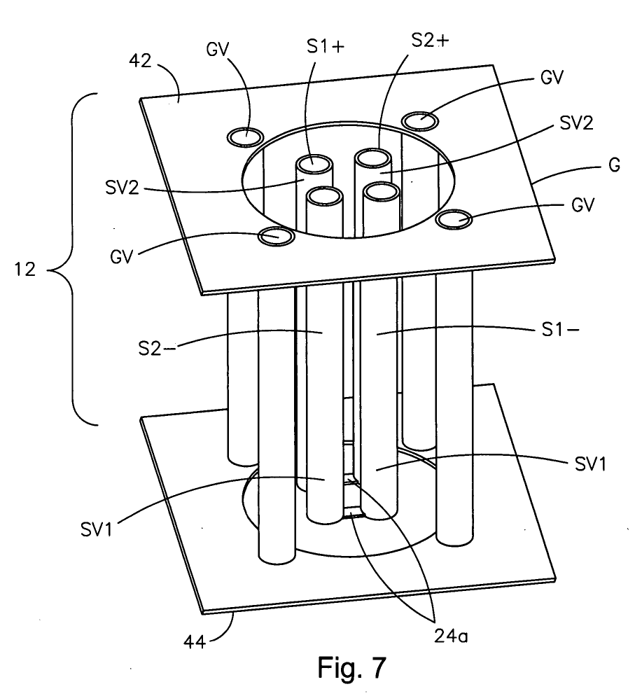

FIG. 7 depicts an example of an alternative midplane via arrangement, according to another embodiment of the invention. The via arrangement is similar to the via arrangement shown in FIG. 6D. That is, first linear arrays of vias SV1, SV2, GV may be disposed to receive columns of electrical contacts from a first midplane connector 14 located on a first side 42 of the midplane 12. Second linear arrays of vias SV1, SV2, GV may be disposed to receive columns of electrical contacts 20 from a second midplane connector 14 that is disposed orthogonally to the first midplane connector 14. The vias SV1, SV2, GV in each linear array may be arranged in signal-signal-ground arrangement to correspond to a signal-signal-ground arrangement of the connector contacts. Additionally, the vias SV1, SV2 may be parallel one another.

The via arrangement of FIG. 7 may differ from that of FIG. 6D. For example, the via arrangement of FIG. 7 may include traces 24a connecting signal vias SV1, SV1 and SV2, SV2 only at one side 44 of the midplane 12. That is, the traces 24a connecting signal vias SV1, SV1 and SV2, SV2 may be located at the back face 44 of the midplane 12 but may be absent from the front face 42 of the midplane 12. Thus, in the example arrangement of FIG. 7, there may be two traces 24a versus the four traces 24a of FIG. 6D. The two traces 24a may electrically connect a differential signal S1−, S1+ of one connector 14 with a differential signal pair S2−, S2+ of a corresponding midplane connector 14.

It should be noted that the signal vias SV1, SV2 of FIG. 7 may include an “unused” end portion on the side 42 of the midplane 12 that does not include traces 24a. That is, an end of the signal via SV1, SV2 located on the side of the midplane 12 devoid of traces may not be disposed to receive a contact 19 of the midplane IMLA 18, and thus may be a stub. As herein described, in alternative midplane via arrangements, such stubs may be removed by back drilling or other suitable methods so that signal/ground via SV1, SV2, GV portions that are not disposed to receive a contact of a midplane IMLA 18 and that are not connected to an adjacent via by a trace 24a are removed from the midplane 12. Removal of stubs may improve the electrical performance of the midplane 12.

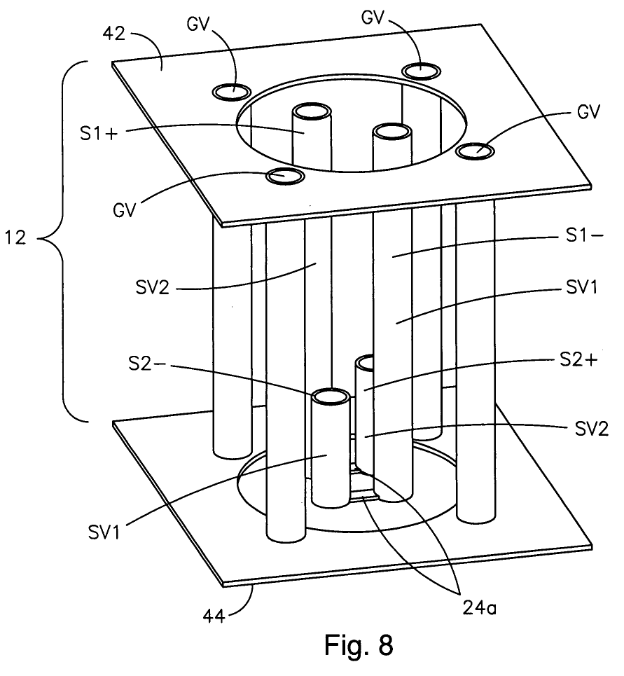

FIG. 8 depicts an alternative example of a midplane 12 via arrangement, according to another embodiment of the invention. The via arrangement of FIG. 8 is similar to the via arrangement of FIG. 7 but differs at least in that stubs have been removed from the via arrangement.

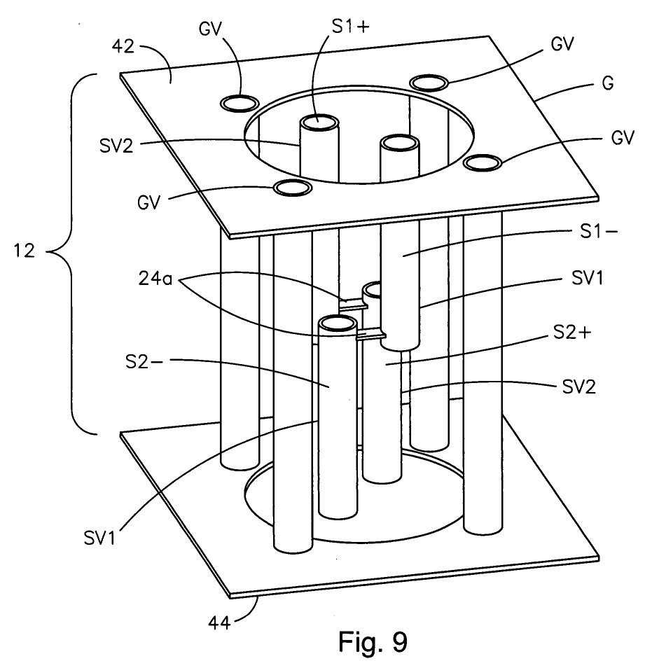

FIG. 9 depicts an alternative example of a midplane via arrangement, according to another embodiment of the invention. A first linear array of vias SV1, SV2, GV may be disposed to receive a column of electrical contacts 20 from a first midplane connector 14 located on a first side 42 of the midplane 12. A second linear array of vias SV1, SV2, GV may be disposed to receive a column of electrical contacts 20 from a second midplane connector 14 that is disposed orthogonally to the first midplane connector 14 on a back face 44 of the midplane 12. The vias in each linear array may be arranged in signal-signal-ground S1+, S1−, G arrangement to correspond to the signal-signal-ground arrangement of the connector contacts.

All ground vias GV of the first and second linear arrays of vias may extend from the back face 44 to the front face 42 through the midplane 12. Each signal via SV1, SV2 of the linear arrays, however, may extend from a face 42, 44 of the midplane 12 partially into the midplane 12. That is, the signal vias SV1, SV2 of the first linear array may extend from the front face 42 of the midplane 12 into the midplane 12 but may not extend through to the back face 44 of the midplane 12. Rather, the signal vias SV1, SV2 may extend to about midway through the midplane 12. Likewise, each signal via SV1, SV2 of the second linear array may extend from the back face 44 of the midplane 12 and terminate about mid-way through the midplane 12. Additionally, the signal vias SV1, SV1 and SV2, SV2 may be connected by traces 24a. Thus, the stubs of each via SV1, SV2—that is, the portion of each via that would not be disposed to receive an electrical contact of an electrical connector and that would not be connected to an adjacent via by a trace 24a—may be removed. Such removal may be by back drilling or other suitable method.

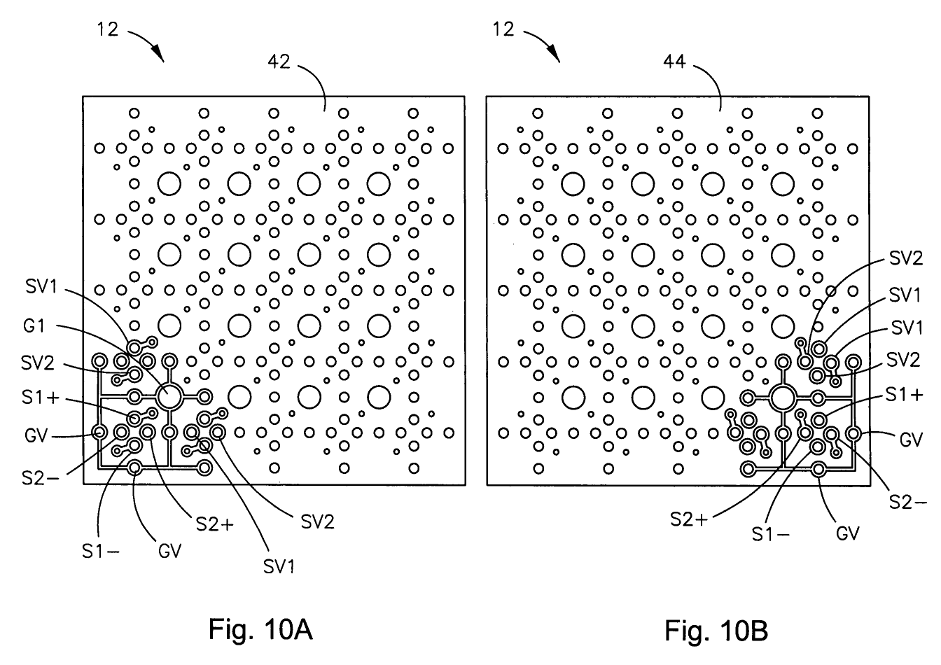

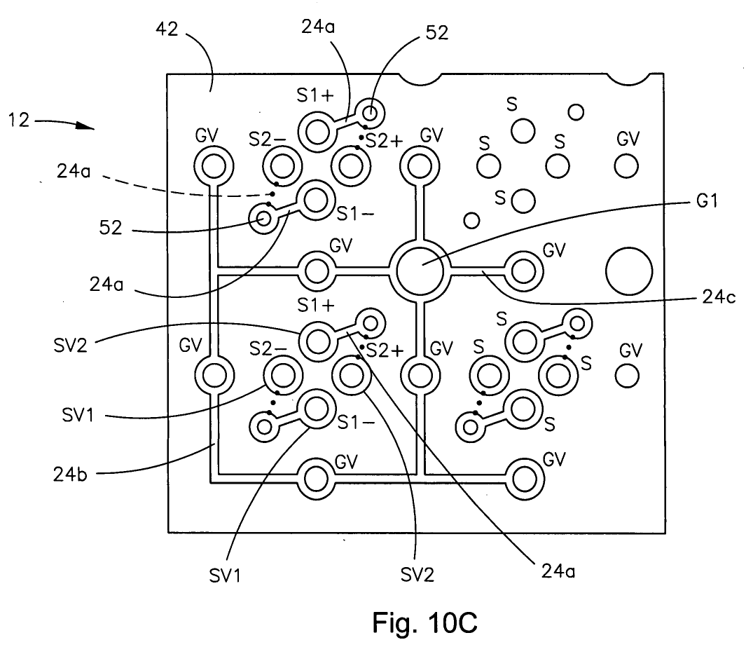

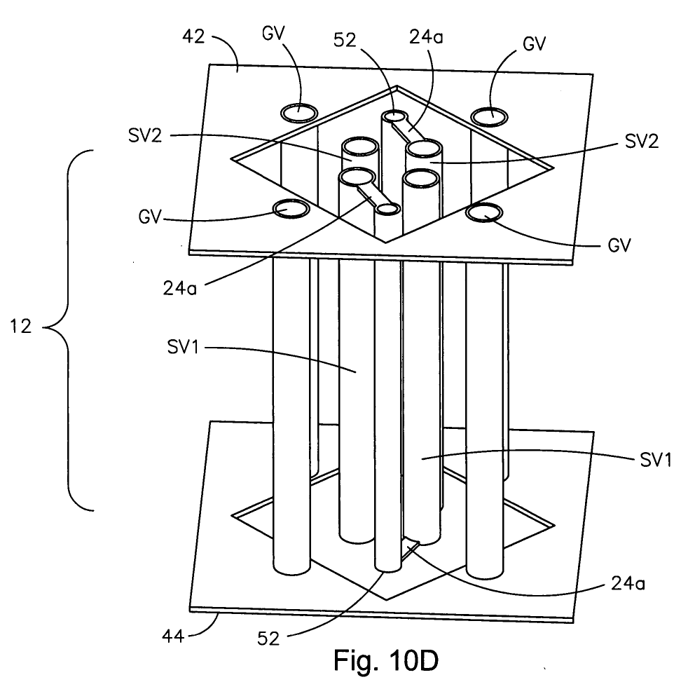

FIGS. 10A and 10B depict a front face 42 and a back face 44, respectively, of an example midplane 12 footprint, according to one embodiment of the invention. FIG. 10C depicts example ground G and signal S1+, S1−,S2+, S2− assignments associated with the footprints depicted in FIGS. 10A and 10B. FIG. 10D depicts a perspective view of midplane vias SV, GV and small vias 52 arranged to provide a portion of the footprints depicted in FIGS. 10A and 10B.

As shown in FIGS. 10A and 10B, linear arrays of vias SV1, SV2, GV may be disposed (vertically, as shown) on one side 42 of the midplane 12 to receive columns of electrical contacts 20 from a midplane connector 14 positioned on midplane 12. Linear arrays of vias SV1, SV2, GV may be disposed (horizontally, as shown) on a back face 44 of the midplane 12 to receive columns of electrical contacts 20 from a second midplane connector 14 that is disposed orthogonally to the other midplane connector 14. The vias SV1, SV2, GV in each linear array may be arranged in signal-signal-ground arrangement to correspond to a signal-signal-ground S1−, S1+, G arrangement of the connector contacts 20. The vias SV1, SV2 additionally may be parallel to one another.

As shown in FIG. 10C, the ground vias GV may be interconnected by electrically conductive traces 24b that run horizontally and vertically as shown. Thus, electrical ground may track through the midplane 12. Large ground vias G1 may be provided between pairs of signal vias SV1, SV2 to reduce crosstalk between pairs S1+, S1− and S2+, S2−. A large ground via G1 may be interconnected by a trace 24c to the other ground vias GV.

To track signal pairs through the midplane 12, signal vias SV1, SV2 may be interconnected by electrically conductive traces 24a as shown. The footprints on the front and back face 42, 44 may include a number of small signal vias 52 in addition to the press-fit signal vias SV1, SV2. The small signal vias 52 may not receive connector tail ends 28 of midplane IMLA 18 contacts 20, and may provide signal communications through the midplane 12. Such small signal vias 52 may be spaced farther apart than press-fit vias SV to increase impedance through midplane 12. The press-fit signal vias SV may have diameters of about 0.6 mm for a drilled hole or about 0.5 mm for a finished hole, though it is anticipated that the press-fit signal vias SV may have diameters in the range of about 0.4 mm to about 0.8 mm. The small signal vias 52 may have diameters of about 0.3 mm, though it is anticipated that the small signal vias may have diameters in the range of about 0.2 mm to about 0.5 mm.

FIG. 10C includes dotted lines to show traces that may be located on the back face 44 of the midplane 12. As shown, signal vias SV1, SV2 arranged in a vertical linear array may correspond to a first differential signal pair S1−, S1+ of a midplane connector 14. Similarly, signal vias SV1, SV2 arranged in a horizontal linear array may correspond to a second differential signal pair S2−, S2+ of a second midplane connector 14. A first trace 24a on the front face 42 footprint is represented by a solid line and electrically connects a signal via SV1 associated with a signal contact S1− of a midplane IMLA 18 to a respective first small via 52. A second trace 24a on the front face 42 is represented by a solid line and electrically connects a second signal via SV2 associated with a second signal contact S1+ with a second small via 52.

As shown in FIGS. 10C and 10D, the first small via 52 may be electrically connected to a signal via SV1 associated with signal contact S2− by a trace 24a (represented by a dotted line) on the back face 44 of the midplane 12. The second small via 52 may be electrically connected to a signal via SV2 associated with signal contact S2+. In this way, the small vias 52 electrically connect signal contacts S1−, S2− and S1+, S2+ of the horizontal and vertical linear arrays. Short signal traces 24a on the front and back of the midplane 12 may eliminate a need for stubs or eliminate the need for back drilling.

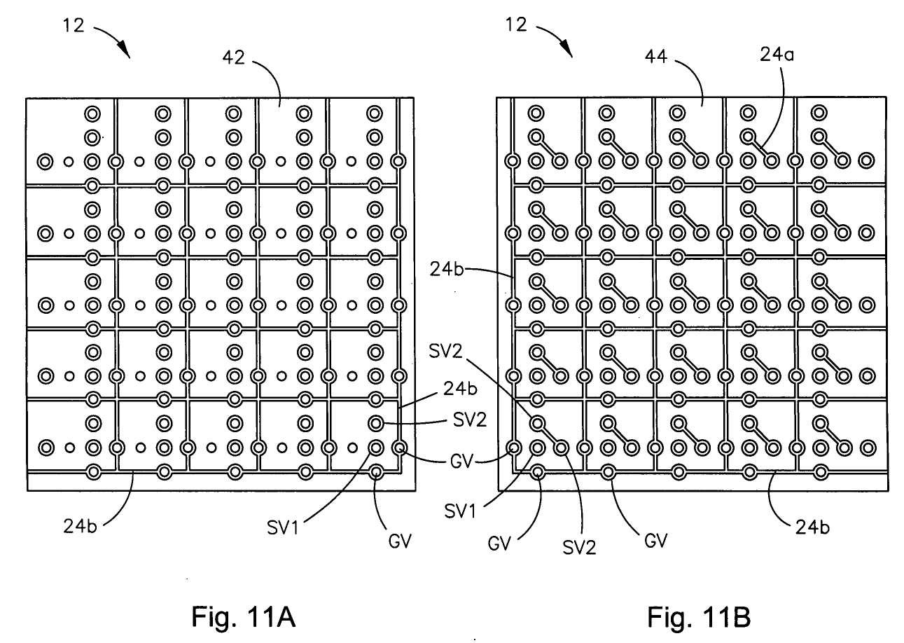

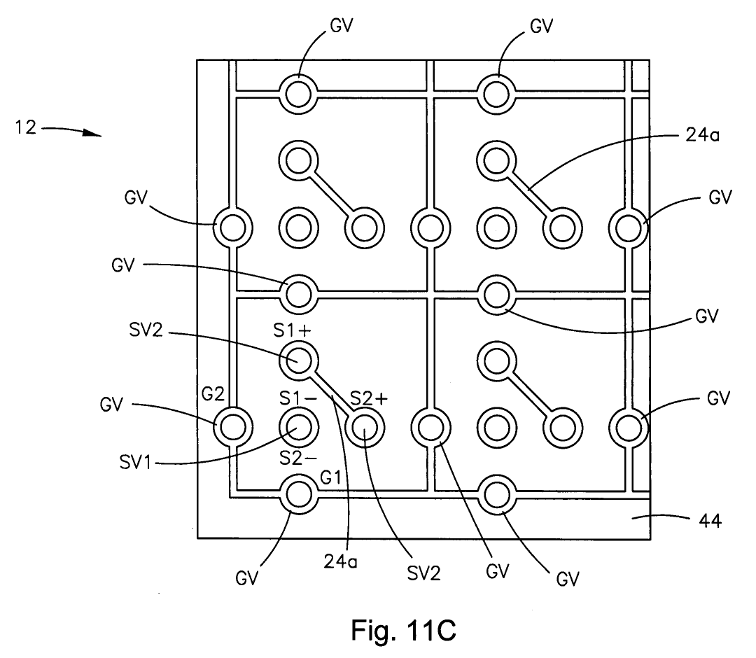

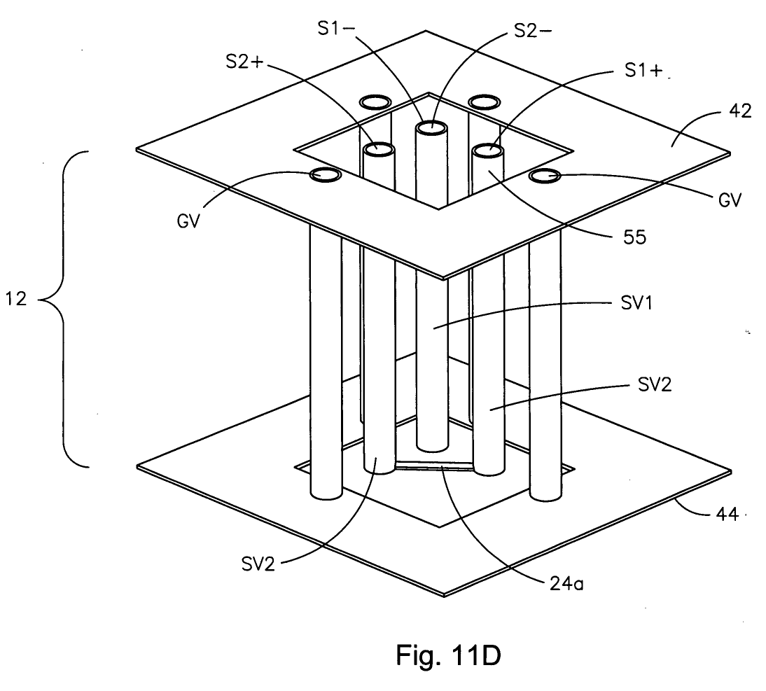

FIGS. 11A and 11B depict a front face 42 and a back face 44, respectively, of an example midplane 12 footprint with maximized via-to-via spacing and optional back-drilling (once per differential signal pair S1+, S1−; S2+, S2−). FIG. 11C depicts example ground G1, G2 and signal assignments S1+, S1−; S2+, S2− associated with the footprints depicted in FIGS. 11A and 11B. FIG. 11D depicts a perspective view of midplane vias SV1, SV2, GV arranged to provide a portion of the footprints depicted in FIGS. 11A and 11B.

As shown in FIGS. 11A and 11B, linear arrays of vias SV1, SV2, GV may be disposed (vertically, as shown) on a first side 42 of the midplane 12 to receive columns of electrical contacts 20 from a first midplane connector 14. Linear arrays of vias SV1, SV2, GV may be disposed (horizontally, as shown) on a back face 44 of the midplane 12 to receive columns of electrical contacts 20 from a second midplane connector 14 that is disposed orthogonally to the first midplane connector 14. The vias SV1, SV2, GV in each linear array may be arranged in signal-signal-ground arrangement to correspond to the signal-signal-ground arrangement of the connector contacts 20. Additionally, the vias SV1, SV2, GV may be parallel to each other.

As shown, the ground vias GV may be interconnected by electrically conductive traces 24b that run horizontally and vertically as shown. Thus, grounds G may track through the midplane 12.

As shown in FIG. 11C, signal vias SV may correspond to a first differential signal pair S1+, S1− in a first midplane IMLA 13. Similarly, signal vias SV may correspond to a second differential signal pair S2+, S2− in another midplane IMLA 13. A trace 24a may electrically connect signal vias SV. The trace 24a connecting signal vias SV may be located only at one side of the midplane 12, such as the back face 44, as depicted in FIGS. 11B and 11D. That is, the trace connecting signal vias SV may be located at the back face 44 of the midplane 12 but may be absent from the front face 42 of the midplane 12.

The footprint may be disposed such that signal via SV1 is a shared via. That is, the electrical signal contact S1− of respective midplane IMLAs 18 may be received into the same signal via SV1 from opposite sides of the midplane 12. The trace 24a between signal vias SV2, SV2 may enable each signal pair S1+, S2+ to track through the midplane 12. As shown best in FIG. 11D, a signal via SV may include a stub 55 extending to the front face 42 of the midplane 12.

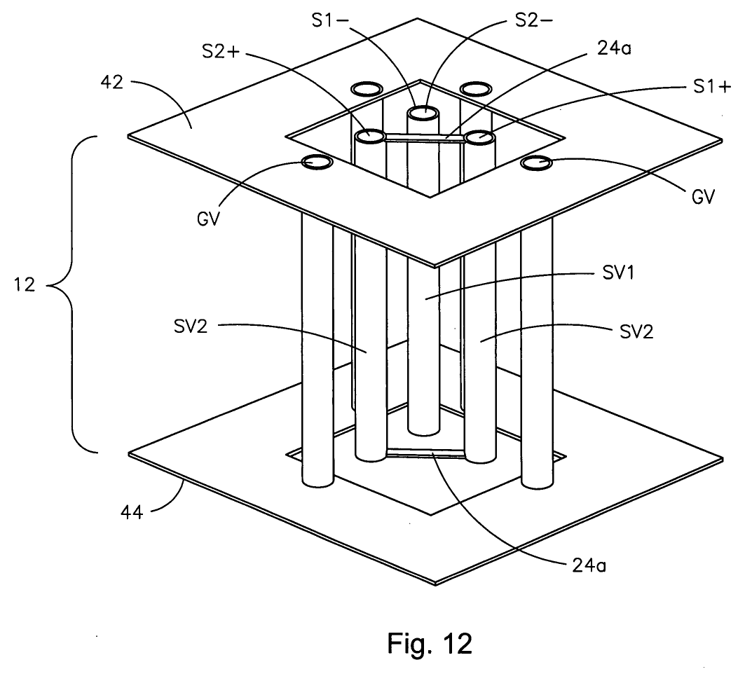

FIG. 12 depicts a perspective view of an alternative example of a midplane via arrangement, according to another embodiment of the invention. The midplane via arrangement may be similar to the via arrangement shown in FIG. 11D. Linear arrays of vias SV1, SV2, GV may be disposed on a first face 42 of the midplane 12 to receive columns of electrical midplane contacts 20 from a first midplane connector 14. Linear arrays of vias SV1, SV2, GV may be disposed on a second face 44 of the midplane 12 to receive columns of electrical midplane contacts 20 from another midplane connector 14 that is disposed on the other face of midplane 12. The vias SV1, SV2, GV in each linear array may be arranged in signal-signal-ground arrangement S1+, S1−, G to correspond to the signal-signal-ground arrangement of the midplane connector contacts 20.

The via arrangement may provide, as with the arrangement described with regard to FIG. 11C, a shared via SV1. There are two traces 24a in the FIG. 12 embodiment. As shown, the traces 24a connecting signal vias SV2, SV2 may be located at the front face 42 and the back face 44 of the midplane 12.

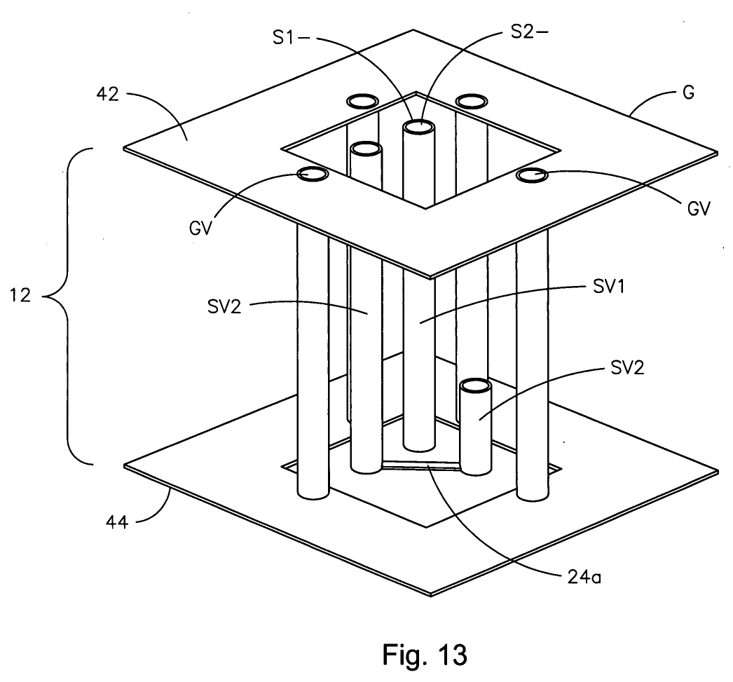

FIG. 13 depicts an alternative example of a midplane via arrangement, according to another embodiment of the invention. The via arrangement shown in FIG. 13 is similar to that shown in FIG. 11 D with the stub removed from the signal via SV2.

FIG. 14A depicts a front face 42 of an alternative example midplane footprint. FIG. 14B depicts a transparent view of the midplane 12 of FIG. 14A, showing both the front 42 and back face 44 footprints. FIG. 14C depicts a perspective view of a midplane IMLA 18 connected to a midplane 12.

As shown in FIGS. 14A and 14B, a first linear array of vias SV1, GV may be disposed (vertically, as shown) to receive columns of electrical contacts 20 from a first midplane connector 14. The first linear array may include two ground vias GV and a signal via SV1. A second linear array of vias SV1, GV may be disposed (horizontally, as shown) to receive columns of electrical midplane contacts 20 from a second midplane connector 14 that is disposed opposite the first midplane connector 14. The second linear array of vias SV1, GV may also include two ground vias GV and a signal via SV1. The signal via SV1 of the first linear array may be a shared via SV1 in that it is the same as the signal via of the second linear array. Thus a contact 20 of a midplane IMLA 18 inserted into the signal via SV1 from the front face 42 of the midplane 12 may share the via SV1 with, and thus electrically connect to, a contact 20 of a midplane IMLA 18 inserted into the signal via SV1 from the back face 44 of the midplane 12.

The front and back faces 42, 44 of the midplane 12 may additionally include a signal via SV2 that is offset from the respective linear array of vias SV1, GV. The offset signal via SV2 may be electrically connected to an elongated pad 60 that extends in a direction toward the respective linear array. The offset via SV2 may also be a shared surface via, in that the via SV2 extends from the front face 42 to the back face 44, and the elongated pads 60 on the front and back faces 42, 44 of the midplane 12 may be electrically connected to the same via SV2. The elongated pads 60 may be disposed for electrical connection with surface-mount contacts 62 (FIG. 14 C) of respective IMLAs 18. The pads 60 and vias SV1, SV2, GV may be configured such that the impedance through the midplane 12 is matched to, for example, 100±10 Ohms, 85±10 Ohms for differential signal transmission or to, for example, about 50 Ohms for single-ended applications.

As shown in FIG. 14C, the midplane connector IMLAs 18 may include ground and signal contacts with press-fit connector tails 28. In addition to press-fit contacts 28, the IMLA 18 additionally may include signal or ground contacts 20 that each include a surface mount contact tail, such as a flexible J-lead 62. A J-lead 62 may be a terminal end of a contact 20 that extends in a direction generally orthogonal to the rest of the contact and parallel to the surface of a midplane 12 when the midplane IMLA 18 is attached to the midplane 12. The J-lead 62 of the midplane signal contacts 20 may extend an appropriate length and in an appropriate direction such that it is capable of being attached by soldering, compressing, or other appropriate methods to a respective elongated pad 60 formed on the face of the midplane 12 when the midplane IMLA 18 is connected to the midplane 12. Other methods of attachment include compliant beam, press-fit engagement without solder, with the press fit tails maintaining the normal force. Thus, the J-leads 62, in conjunction with the elongated pads 60 connected to the shared vias SV2, along with the shared via SV1 included in respective linear arrays of the front and back face 42, 44 of the midplane 12, track signal pairs through the midplane 12. The press-fit contacts 28 generally hold the surface mount contact tails in electrical contact with the pad 60. The surface mount contact tails can be in-line with the press-fit contacts 28 or can extend outwardly from the inline axis of the surface mount contact tails.

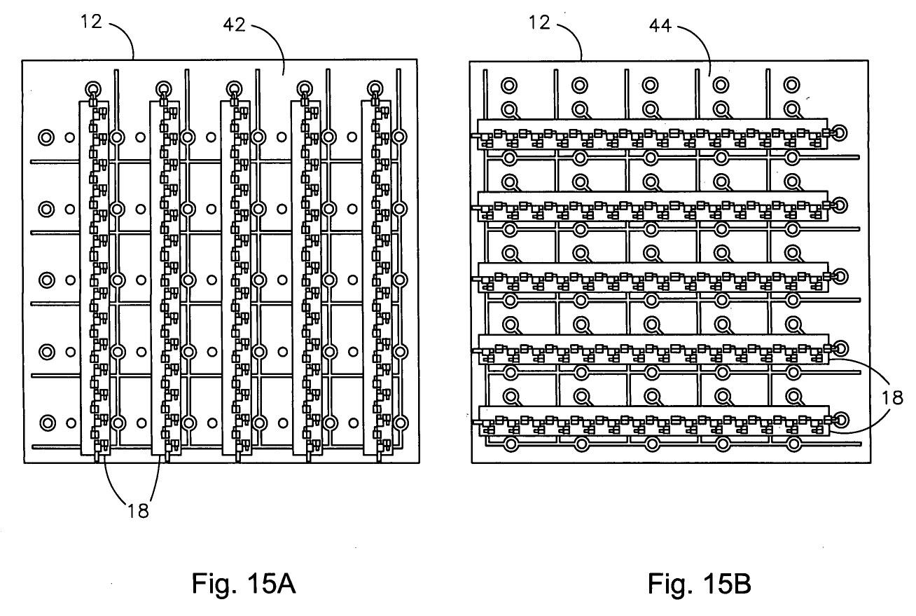

FIGS. 15A and 15B depict a cutaway view of a front face 42 and a back face 44, respectively, of a midplane 12 having a plurality of midplane IMLAs 18 assembled thereto.

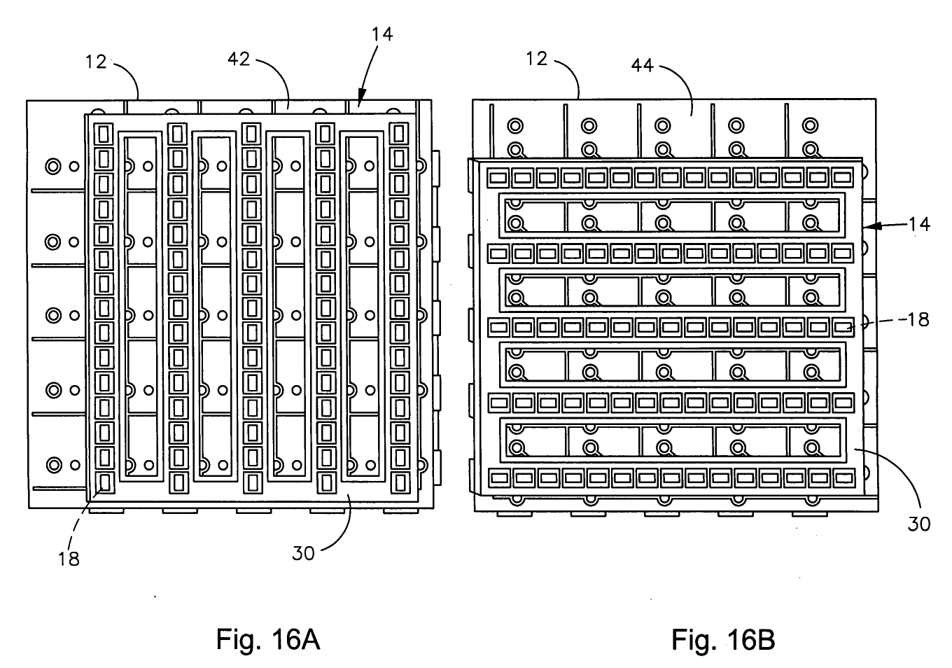

FIGS. 16A and 16B depict a cutaway view of a front face 42 and a back face 44, respectively, of a midplane 12 having a plurality of midplane connectors 14 with the midplane connector housings 30 positioned over the midplane IMLAs 18.

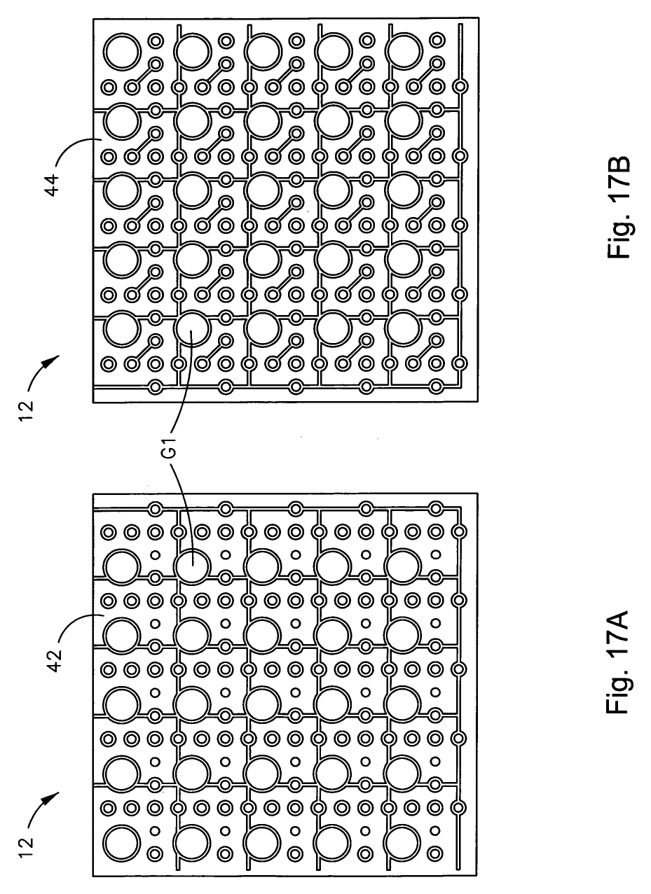

FIGS. 17A and 17B depict another example midplane footprint with maximized via-to-via spacing, as depicted in and described with regard to FIGS. 11A and 11B. Additionally, the footprint includes optional large ground vias G1.

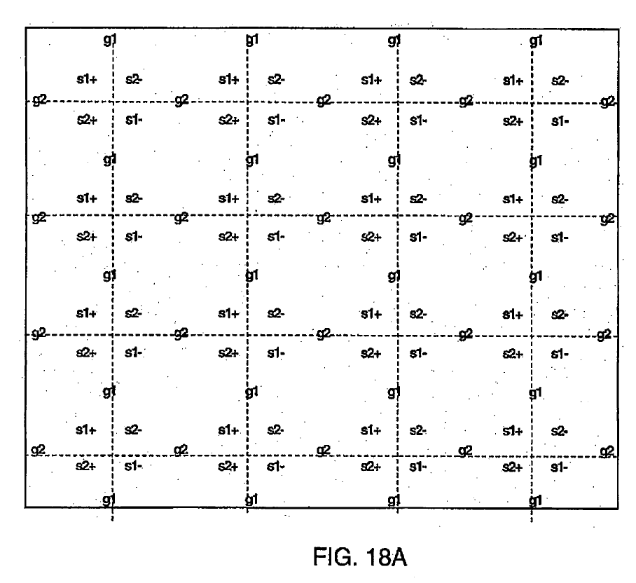

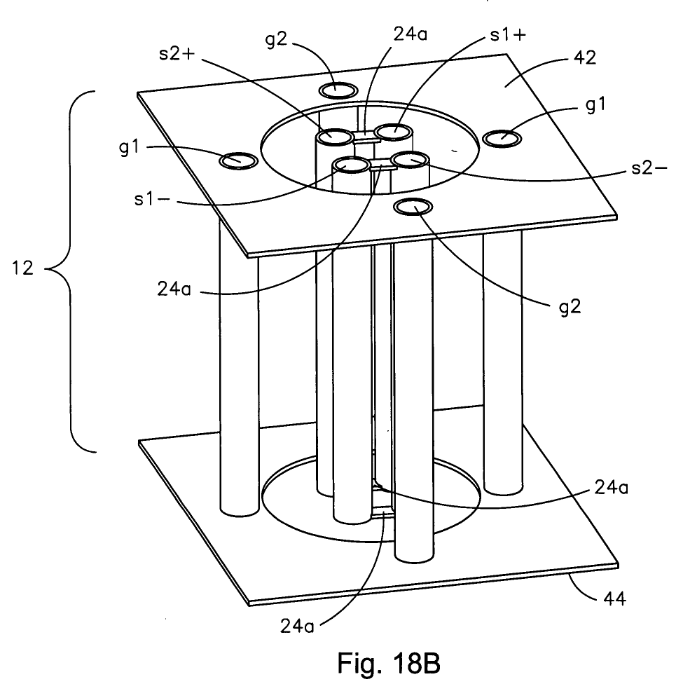

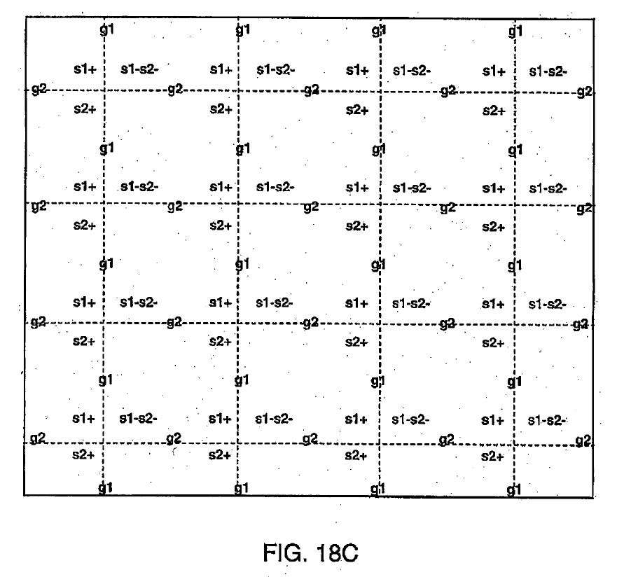

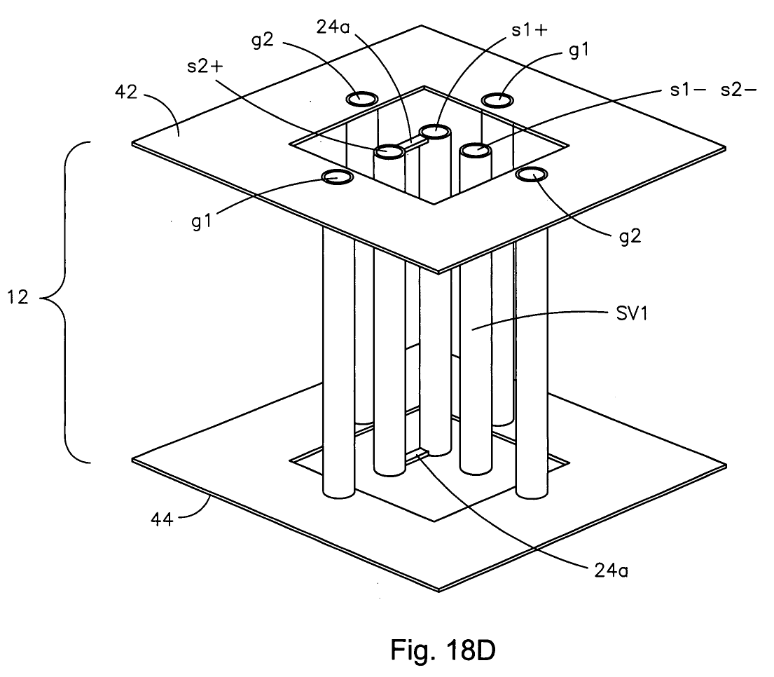

FIGS. 18A and 18B depict, respectively, example ground g1, g2 and signal assignments s1+, s1−, s2+, s2− associated with an alternative midplane footprint and a perspective view of an example midplane 12 via arrangement associated with the footprint. The footprint may be used with electrical connectors that include midplane IMLAs 18 in which signal contacts 20 terminal ends jog to one side with regard to the contact column in the midplane IMLA 18, depicted by the dotted vertical and horizontal lines.

The footprint may include arrays of ground vias g1, g1 and signal vias s1+, s1− (vertically, as shown) disposed to receive columns of electrical midplane contacts 20 from a first midplane connector 14 located on a first face 42 of the midplane 12. The ground vias g1 may define a centerline of each vertical array denoted by the vertical dotted line. Signal contacts s1+ and their associated signal vias may be offset a distance, for example, to the left of the centerline, and signal s1− and their associated vias may be offset the distance to the right of the centerline defined by the ground vias g1. The location of the signal vias s1+, s1− and the ground vias g1 may correspond to contact terminal ends of the midplane IMLA 18 that are likewise offset from a centerline of the midplane IMLA 18.

The footprint additionally may include arrays of ground vias g2 and signal vias s2+, s2− (horizontally, as shown) disposed to receive columns of electrical contacts from a midplane connector 14 located on the back face 44 of the midplane 14. The ground vias g2 may define a centerline of each horizontal array, denoted by the horizontal dotted line. Signal contacts s2+ and their associated vias may be offset a distance, for example, below the centerline, and signal contacts s2− and their associated vias may be offset the distance above the centerline defined by the ground vias g2. The location of the signal vias s2+, s2− and the ground vias g2 may correspond to terminal ends of midplane contacts 20 of the midplane IMLA 18 that are likewise offset.

The signal vias may be located such that the minimum distance between, for example, a signal via that receives signal contact s1+ and a signal via that receives signal contact s2− may be about 1.4 mm. As may be seen in FIG. 18B, traces 24a on the midplane 12 may be used to electrically connect, for example, the s1+ and s2+ signal contact vias and the s2− and s1− signal contact vias. Such traces 24a may be located on both the front and back faces 42, 44 of the midplane 12. Alternatively, traces may be located on either the front or back face 42, 44 of the midplane 12 or midway between the front and back face 42, 44 of the midplane 12.

FIGS. 18C and 18D depict, respectively, example ground g1, g2 and signal s1+, s1−, s2+, s2− assignments associated with an alternative midplane footprint and a perspective view of an example midplane via arrangement associated with the footprint. The footprint may be used with electrical connectors that include midplane IMLAs 18 in which signal contact terminal ends jog to one side with regard to the contact column in the IMLA 18, depicted by the dotted vertical and horizontal lines. Additionally, the footprint may be similar to that depicted in FIGS. 18A and 18B except that the arrangement may include a shared via SV1 (FIG. 18D). That is, the electrical midplane contacts 20 of respective electrical midplane connectors 14 that correspond to signals s1− and s2− may be received into the same signal via SV1 from opposite faces 42, 44 of the midplane 12. Thus, traces 24a electrically connect s1+ and s2+ signal contacts and the shared signal via SV1 electrically connects s1− and s2− signal contacts through the midplane 12.

The signal contacts s1+, s1− s2−, s2+ and their associated midplane vias may be located such that the minimum distance between, for example, signal s1+ and a signal s1−s2− may be about 1.4 mm. Traces 24a may be located on either the front or back face 42, 44 of the midplane 12 or midway between the front and back face 42, 44 of the midplane 12.

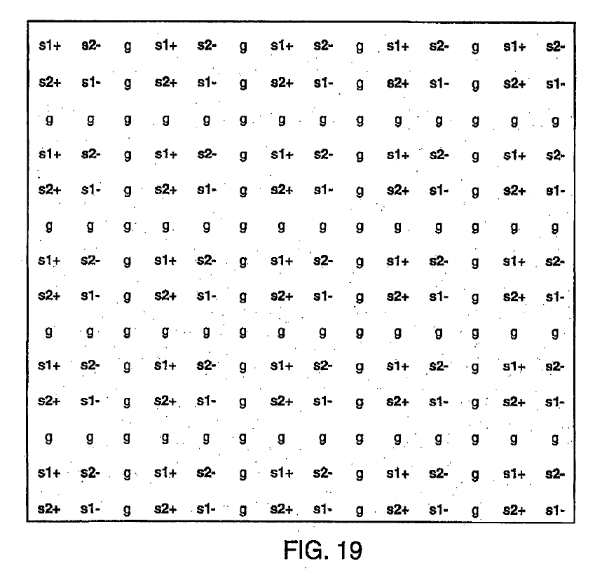

FIG. 19 depicts a diagram of an example contact arrangement for an electrical connector adapted to be orthogonally connected to a similarly-arranged connector. Such an electrical connector may include fourteen IMLAs 18, 24, each including fourteen or some other number of contacts. Ten of the IMLAs 18, 24 may be arranged into five IMLA pairs with each IMLA of an IMLA pair including contacts in a signal-signal-ground configuration. Thus, the arrangement depicted in FIG. 19 includes fifty differential signal contact pairs. In between each of the five pairs of IMLAs may be an IMLA of ground contacts. Alternatively, the IMLA of ground contacts may be replaced with a vertical shield. Traces 24a on the midplane 12 connect the s1+ signal contacts to the s2+ signals contacts and connect the s1− signal contacts to the s2− signal contacts.

With continuing reference to FIG. 19, the first IMLA 18, 24 may be in a signal-signal-ground configuration. A first contact 20 of the first IMLA 18, 24 may be a signal contact s1+ and a second signal contact s2+ in the same IMLA 18, 24 or in an adjacent IMLA 18, 24 may be adjacent to the first signal contact s1+. A second IMLA 18, 24 adjacent to the first midplane IMLA 18, 24 may likewise be in a signal-signal-ground configuration. A first contact 20 of the second midplane IMLA 18, 24 may be a signal contact s2− and a second contact 20 may be a signal contact s1−. The signal contact s1+ may form a differential signal pair with the signal contact s1− and the signal contact s2− may form a differential signal pair with a signal contact s2+. Thus, the signal contact pairs may be diagonally opposed to one another in adjacent IMLAs 18, 24. The contact s2+ may be spaced about 1.85 mm from the contact s1+. Likewise, the contact s2− may be spaced about 1.85 mm from the contact s1+.

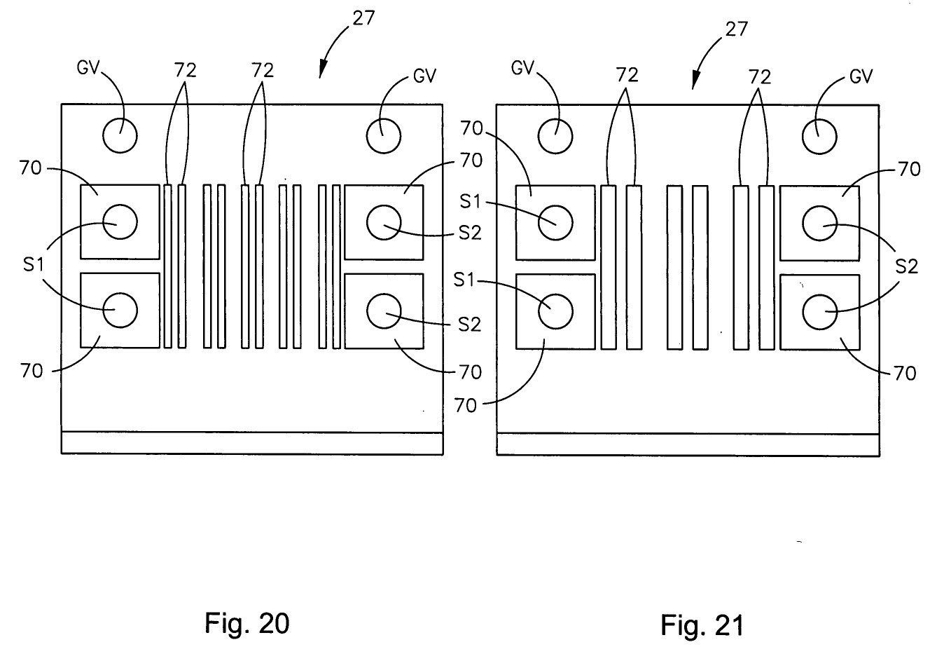

FIG. 20 depicts a portion of an alternative example of a daughtercard 27 footprint. The footprint may include two signal vias S1 each surrounded by an anti-pad 70. The signal vias S1 may form a linear array with a ground via GV. A second linear array may likewise include two signal vias S2, each surrounded by an anti-pad 70, and a ground via GV. The linear arrays may be spaced apart a distance such as, for example, about 4.2 mm. Five pairs of traces 72 may be located in between the two linear arrays. Each trace 72 within a pair of traces may be spaced apart a first distance that may be less than a distance between trace pairs. For example, traces 72 within a pair of traces may be spaced apart about 0.10 mm. Pairs of traces may be spaced from other pairs of traces a distance of about 0.35 mm.

FIG. 21 depicts a portion of an alternative example of a daughtercard 27 footprint. The footprint may include two signal vias S1, each surrounded by an anti-pad 70. The signal vias S1 may form a linear array with a ground via GV. A second linear array may likewise include two signal vias S2, each surrounded by an anti-pad 70, and a ground via GV. The linear arrays may be spaced apart a distance such as, for example, about 4.2 mm. Three pairs of traces 72 may be located in between the two linear arrays. Each trace 72 within a pair of traces may be spaced apart a first distance that may be less than the distance between trace pairs. For example, traces 72 within a pair of traces may be spaced apart about 0.20 mm. Pairs of traces may be spaced from other pairs of traces a distance of about 0.54 mm.

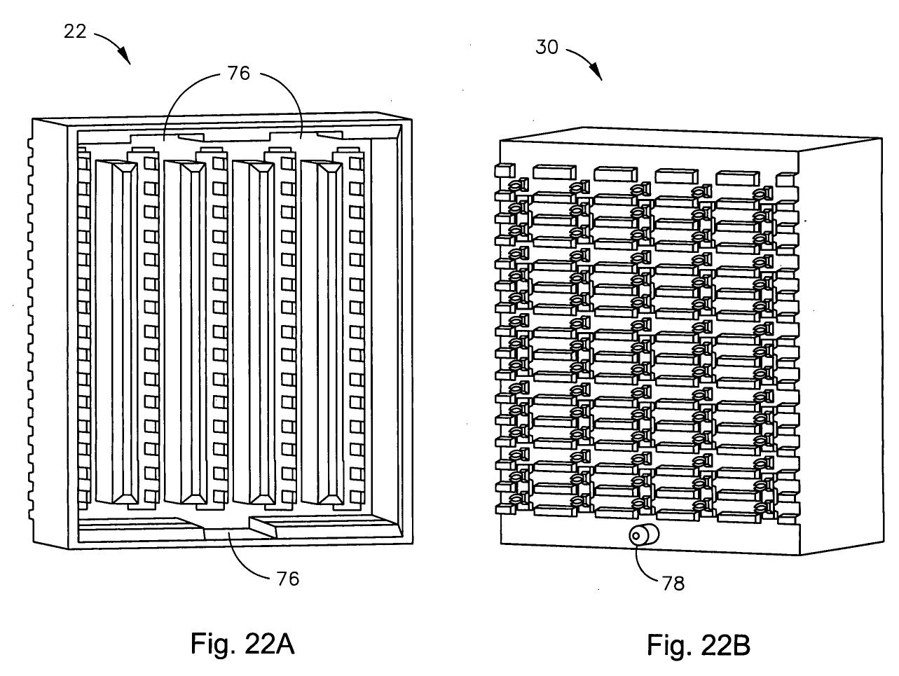

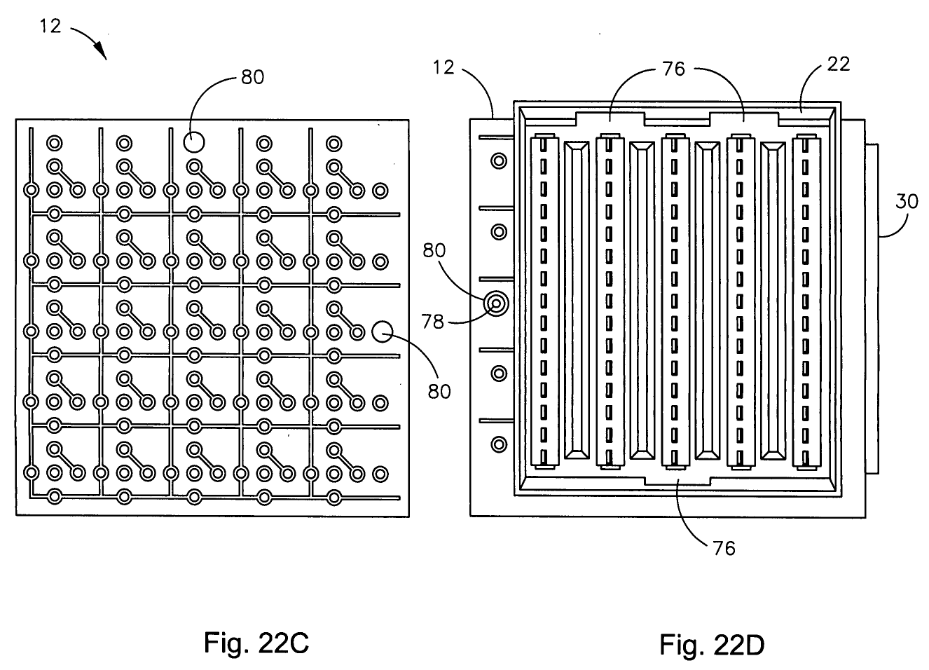

FIGS. 22A-D depict example connector polarization features. As shown in FIG. 22A, the right angle connector housing 22 or the midplane connector housing 30 may include a plurality of alignment cavities 76. To ensure that the connectors 14, 16 may be mated in only one orientation, the header assembly may include, for example, two alignment cavities 76 at one end and only one alignment cavity 76 at the other end.

As shown in FIG. 22B, the midplane connector housing 30 may include one or more polarization pegs 78 that extend therefrom. As shown in FIG. 22C, the midplane 12 may include one or more complementary holes 80 for receiving the one or more polarization pegs 78. The pegs 78 and holes 80 may be disposed between the midplane connector housing 30 and the midplane 12 such that the midplane connector 14 and the right angle connector 16 can be mated in only one orientation (as shown in FIG. 22D, for example).

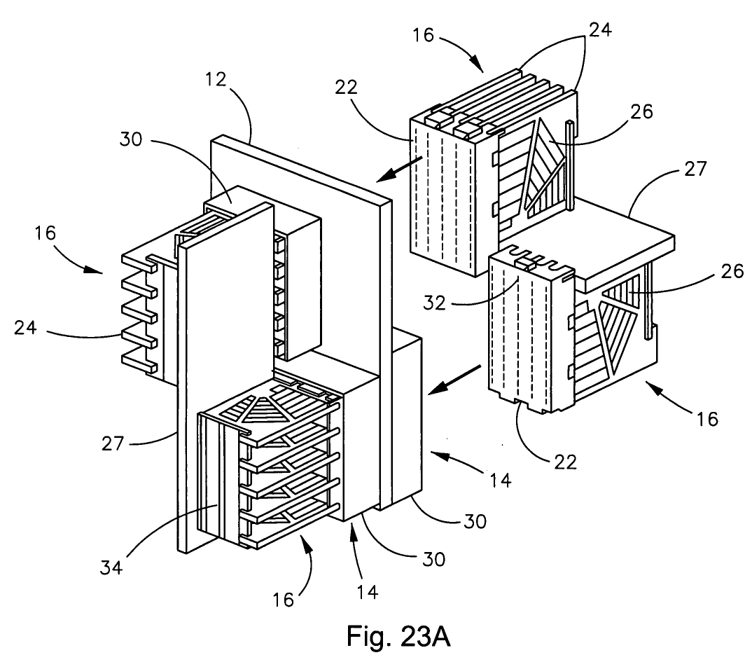

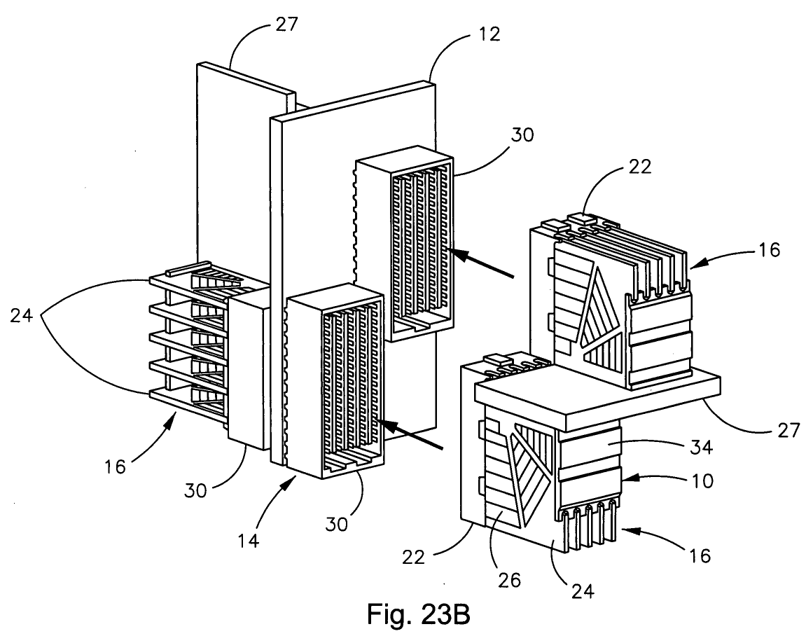

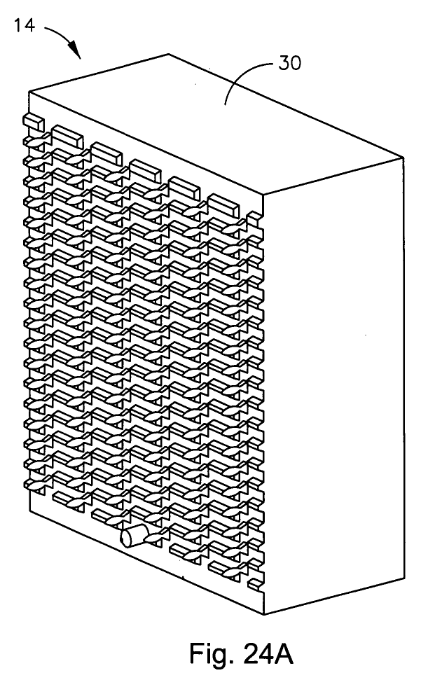

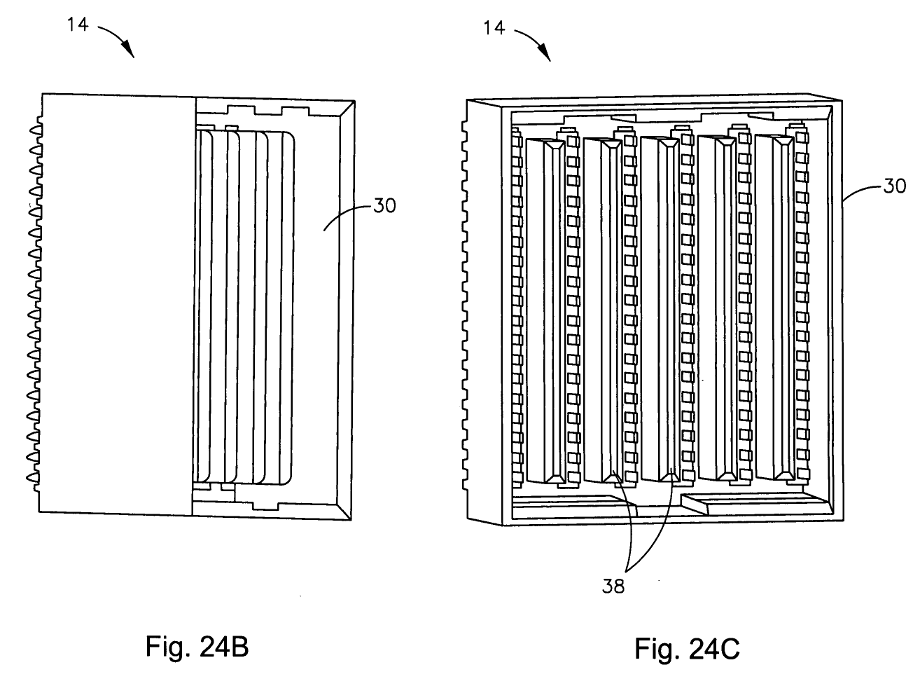

FIGS. 23A and 23B depict an alternative orthogonal connector assembly 10. FIG. 24 depicts a transparent view of the assemblies depicted in FIGS. 23A and 23B. As shown in FIGS. 23A and 23B, first pair of right angle connectors 16 are mounted to opposing faces of a first daughtercard 27 and may be electrically connected to one another. Each right angle connector 16 may be disposed to electrically connect with a respective midplane connector 14. Each right angle connector 16 is shown to include five right angle IMLAs 24, though it should be understood that alternative connectors may include more or less IMLAs. As shown in FIG. 23A, the right angle contacts 26 have female mating ends 32 positioned inside slots in the right angle connector housing 22.

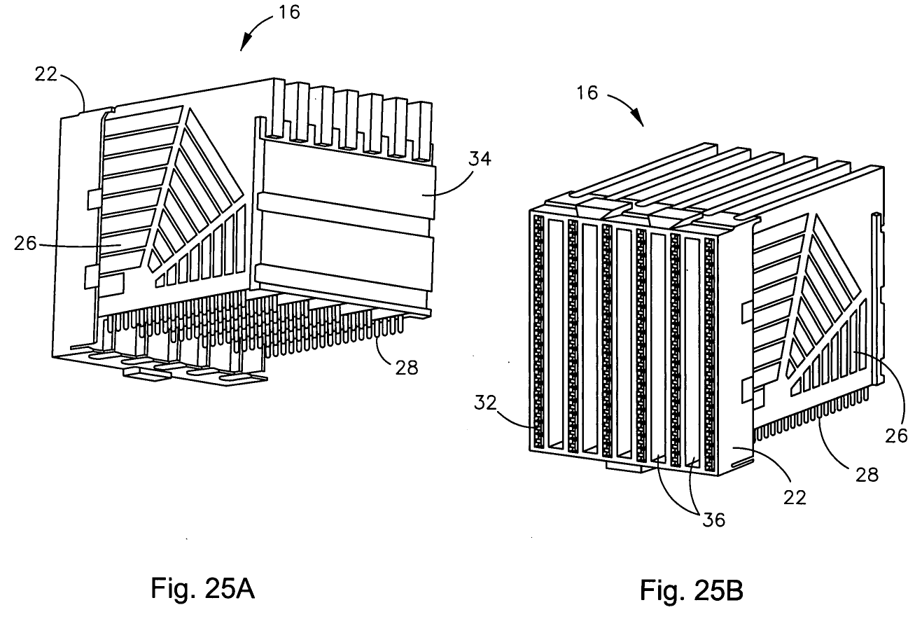

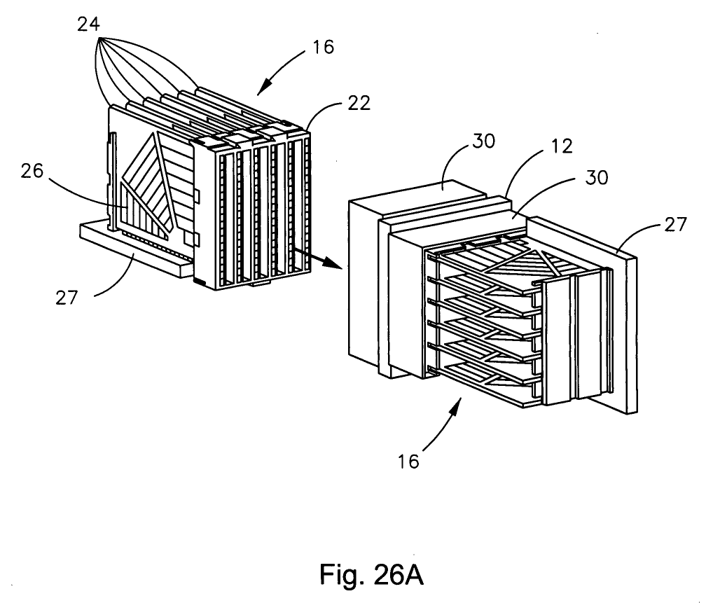

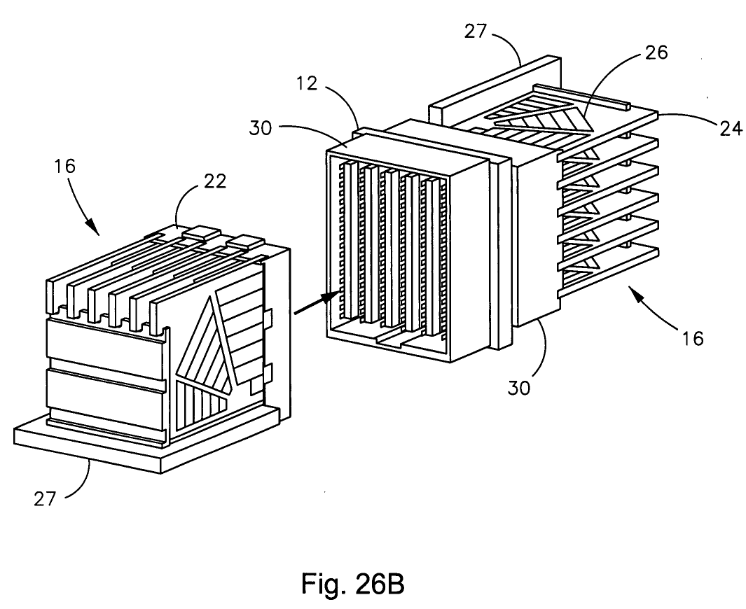

FIGS. 25A-C depict an alternative example of a vertical header/midplane connector 14. FIGS. 26A and 26B depict an alternative example of a right angle connector 16. FIGS. 27A and 27B depict an alternative example of an orthogonal connector assembly 10 that includes the header/midplane connector 14 of FIGS. 25A-25C and the right angle connector 16 of FIGS. 26A and 26B. FIG. 28 depicts a transparent view of the connectors depicted in FIGS. 27A and 27B.

It should be understood that an orthogonal connector system according to the invention may have numerous advantages over prior art orthogonal connector systems. For example, a connector system according to the invention may remove the need for back-drilling. No internal backplane/midplane layers may be required to route high speed differential signals. Fewer vias may be required. Fewer signal routing layers on daughtercard may be required due to wider pitch, such as a 4.2 mm pitch, in a routing direction. Real estate required for board thicknesses may be greatly reduced. All pins need not be orthogonally connected. Both gender styles may have the same footprint. No special connectors are required for PCB layout compatibility. Blade type mating pins can be well-protected by guide posts that mate to cavities defined by the mating connector housing. Press-fit tails need not be inserted into same midplane vias. There may be no need for “anti-pads” in the footprint—just ground vias connected to daughtercards by the connectors and simple traces. There may be no need for routing channels on the boards to run traces to route from the midplane to the connector because vias are being used to do the routing. It has been found that elimination of such routing channels may reduce the number of midplane circuit board layers from 26 to 16.

What is claimed is:

1. A midplane circuit board for forming an orthogonal interconnection between two daughtercards, said midplane circuit board comprising:
a first mating surface having a first linear array of vias disposed in a first direction;
a second mating surface having a second linear array of vias disposed in a second direction that is orthogonal to said first direction; and
one or more signal vias that is offset from a centerline of said first linear array of vias and/or a centerline of said second linear array of vias.

2. The midplane circuit board of claim 1, wherein said first linear array of vias further comprises:
a first signal via of a first differential signal pair;
a first ground via;
wherein said second linear array of vias further comprises:
a first signal via of a second differential signal pair;
a second ground via; and
wherein said one or more offset signal vias further comprises:
a second signal via of said first differential signal pair and/or a second signal via of said second differential signal pair.

3. The midplane circuit board of claim 1, further comprising:
a first pair of ground vias, wherein said first pair of ground vias forms said centerline of first linear array of vias;
a second pair of ground vias, wherein said second pair of ground vias forms said centerline of said second linear array of vias;
one or more of said signal vias of said a first differential signal pair of electrically conductive vias is offset from said first via array centerline; and
one or more of said signal vias of said second differential signal pair of electrically conductive vias is offset from said second via array centerline.

4. The midplane circuit board of claim 1, further comprising an elongate pad on at least one mating surface of said midplane circuit board, wherein said elongate pad is electrically connected to one offset signal via, and wherein said elongate pad is adapted to make electrical contact with a surface-mount contact.

5. The midplane circuit board of claim 1, further comprising:
a first elongate pad on said first mating surface of said midplane circuit board, wherein said first elongate pad extends from one of said signal vias in a first direction; and
a second elongate pad on said second mating surface of said midplane circuit board, wherein said second elongate pad extends from the same signal via as said first elongate pad, and wherein said second elongate pad extends in a second direction that is generally orthogonal to said first direction of said first elongate pad.

6. The midplane circuit board of claim 1, further comprising a shared via, wherein said first signal via of said first differential pair of signal vias of said first linear array and said first signal via of said second differential pair of signal vias of said second linear array comprise said shared signal via, wherein said shared signal via is lies in said first linear array and said second linear array.

7. A circuit board having a plurality of electrical signaling paths for electrically coupling electrical contacts through said circuit board, said circuit board comprising:
a first electrical signaling path for receiving a through-mount electrical contact;
a second electrical signaling path for receiving a surface-mount electrical contact.

8. The circuit board of claim 7, wherein:
said first electrical signaling path further comprises a first signal via adapted to receive a press-fit electrical contact; and
said second electrical signaling path further comprises a second signal via adapted to receive a J-lead electrical contact.

9. The circuit board of claim 8, wherein said second electrical signaling path further comprises:
a signal via extending from a first side to a second side of said circuit board;
a first elongate pad disposed on a first side of said circuit board, said first elongate pad electrically connected to said signal via and extending in a first direction; and
a second elongate pad disposed on said second side of said circuit board, said second elongate pad electrically connected to said same signal via as said first elongate pad, and said second elongate pad extending in a second direction that is orthogonal to said first direction of said first elongate pad.

10. The circuit board of claim 7, wherein said electrical signaling paths comprise one or more of: one or more differential signaling paths, one or more single-ended signaling paths, and combinations of differential signaling paths and single-ended signaling paths.

11. A midplane circuit board for forming an orthogonal interconnection between two daughtercards, said midplane circuit board comprising:
a first mating surface having a first plurality of electrically conductive vias defining a first footprint;
a second mating surface having a second plurality of electrically conductive vias defining a second footprint;
a trace extending between and electrically connecting one of said first plurality of electrically conductive vias to a respective one of said second plurality of electrically conductive vias so that two substantially similar electrical connectors can be received on said first mating surface and said second mating surface of said midplane circuit board and differential signals can pass from said first mating surface to said second mating surface.

12. The midplane circuit board of claim 11, wherein said one or more traces are located on said first mating surface and/or on said second mating surface, and/or between said first mating surface and said second mating surface.

13. The midplane circuit board of claim 11, further comprising one or more partial signal vias, wherein said one or more partial signal vias comprise signal vias that do not extend all the way through said midplane circuit board from said first mating surface to said second mating surface and/or from said second mating surface to said first mating surface.

14. The midplane circuit board of claim 11, further comprising one or more shared signal vias, wherein said one or more shared signal vias comprise signal vias adapted to receive a contact from respective electrical connectors connected to each mating surface of said midplane circuit board.

15. The midplane circuit board of claim 11, wherein said midplane circuit board further comprises:
a first differential signal pair of electrically conductive vias disposed in a first direction, said first differential signal pair of electrically conductive vias extending from said first mating surface toward said second mating surface;
a second differential signal pair of electrically conductive vias disposed in a second direction that is generally orthogonal to said first direction, said second differential signal pair of electrically conductive vias extending from said second mating surface toward said first mating surface.

16. The midplane circuit board of claim 15, wherein:
said first differential signal pair of electrically conductive vias further comprises a first signal via and a second signal via;
said second differential signal pair of electrically conductive vias further comprises a third signal via and a fourth signal via, wherein said third signal via and said fourth signal via are offset from said first signal via and said second signal via;
a first trace extending between and electrically connecting said first signal via and said third signal via; and
a second trace extending between and electrically connecting said second signal via and said fourth signal via.

17. The midplane circuit board of claim 15, wherein:
said first differential signal pair of electrically conductive vias further comprises a first signal via and a second signal via;
said second differential signal pair of electrically conductive vias further comprises said second signal via and a third signal via;
wherein said second signal via comprises a shared signal via adapted to receive a contact from respective electrical connectors connected to each mating surface of said midplane circuit board; and
wherein said third signal via is offset from said first signal via.

18. The midplane circuit board of claim 15, further comprising:
a first ground via disposed adjacent to said first differential signal pair of electrically conductive vias along said first direction;
a second ground via disposed adjacent to said second differential signal pair of electrically conductive vias along said second direction; and
a trace extending between and electrically connecting said first ground via and said second ground via.

19. The midplane circuit board of claim 15, further comprising:
a first pair of ground vias, wherein one or more of said signal vias of said first differential signal pair of electrically conductive vias is located in between said first pair of ground vias;
a second pair of ground vias, wherein one or more of said signal vias of said second differential signal pair of electrically conductive vias is located in between said second pair of ground vias; and
traces extending between and electrically connecting said first pair of ground vias and said second pair of ground vias.

20. The midplane circuit board of claim 19, further comprising one or more offset signal vias, wherein an offset signal via is a signal via that is offset from a respective linear array of vias.

21. The midplane circuit board of claim 15, further comprising:
a first pair of ground vias, wherein said first differential signal pair of electrically conductive vias is associated with said first pair of ground vias, wherein said first pair of ground vias define a first linear array, wherein said first differential signal pair of electrically conductive vias is offset from said first linear array; and
a second pair of ground vias, wherein said second differential signal pair of electrically conductive vias is associated with said second pair of ground vias, wherein said second pair of ground vias define a second linear array that is generally orthogonal to said first linear array, wherein said second differential signal pair of electrically conductive vias is offset from said second linear array; and
traces extending between and electrically connecting said first pair of ground vias and said second pair of ground vias.

22. The midplane circuit board of claim 15, wherein:
each of said differential signal pairs of electrically conducting vias further comprises at least one positive signal path and at least one negative signal path through said midplane;
wherein at least one of said positive signal path and said negative signal path is offset and does not pass straight through said midplane circuit board.

23. The midplane circuit board of claim 11, wherein:
said first plurality of electrically conductive vias further comprises a plurality of differential signal pair of electrically conductive vias and a ground via arranged in a first linear array of vias, wherein said first linear array of vias comprises a repeating pattern of two signal vias and a ground via; and
said second plurality of electrically conductive vias further comprises a plurality of differential signal pair of electrically conductive vias and a ground via arranged in a second linear array of vias, wherein said second linear array of vias comprises a repeating pattern of two signal vias and a ground via, wherein said second linear array of vias is orthogonal to said first linear array of vias.

24. A midplane circuit board for an orthogonal connector system comprising:
a first signal via disposed within a first column of electrically conductive vias, said first column being disposed on a first side of said midplane circuit board in a first direction;
a second signal via disposed within a second column of electrically conductive vias, said second column being disposed on a second side of said midplane circuit board in a second direction that is generally orthogonal to said first direction;
wherein said first signal via is offset from and electrically connected to said second signal via to form a signaling path through said midplane circuit board.

25. The midplane circuit board of claim 24, further comprising:
a plurality of columns of electrically conductively vias arranged parallel to one another in said first direction on said first side of said midplane circuit board;
a plurality of columns of electrically conductively vias arranged parallel to one another in said second direction on said second side of said midplane circuit board;
wherein one or more of said signal vias in said columns on said first side fall outside said columns of signal vias on said second side; and
one or more electrically conductive traces located in or on said midplane circuit board, said traces electrically connecting one or more of said signal vias on said first side of said midplane circuit board to one or more complimentary signal vias on said second side of said midplane circuit board to complete a signaling path through said midplane circuit board.

26. The midplane circuit board of claim 24, further comprising a shared signal via, wherein said shared signal via lies within a column on said first side and a column on said second side of said midplane circuit board.

27. An orthogonal connector system comprising:
a midplane circuit board having a first mating surface and a second mating surface;
a first differential pair of electrically conductive vias on said first mating surface of said midplane circuit board, said first differential pair of electrically conductive vias disposed in a first direction;
a first electrical connector mounted to said first mating surface of said midplane circuit board;
a first differential signal pair of electrical contacts extending from said first electrical connector, wherein said first differential signal pair of electrical contacts are electrically connected to said first differential pair of electrically conductive vias;
a second differential pair of electrically conductive vias on said second mating surface of said midplane circuit board, said second differential pair of electrically conductive vias disposed in a second direction that is generally orthogonal to said first direction;
a second electrical connector mounted to said second mating surface of said midplane circuit board; and
a second differential signal pair of electrical contacts extending from said second electrical connector, wherein said second differential signal pair of electrical contacts are electrically connected to said second differential pair of electrically conductive vias;
wherein said second electrical connector is oriented in a substantially orthogonal relationship to said first electrical connector.

28. The orthogonal connector system of claim 27, further comprising:
a first footprint on said first mating surface of said midplane circuit board;
a second footprint on said second mating surface of said midplane circuit board;
wherein said second footprint is substantially identical to said first footprint and wherein said second footprint is oriented generally orthogonal to said first footprint;
wherein said substantially identical footprints allows the same electrical connector to be coupled to either mating surface of said midplane circuit board.

29. The orthogonal connector system of claim 27, further comprising at least one non-linear signaling path through said midplane circuit board and at least one electrically conductive trace,
wherein at least one signal via of said first differential signal pair of electrically conductive vias and at least one complimentary signal via of said second differential signal pair of electrically conductive vias are offset from one another; and
wherein one of said at least one electrically conductive trace extends between and electrically connects said offset signal vias to form said non-linear signaling path.

30. A first electrical connector comprising:
an electrical housing;
a plurality of contact tails that each extend from a mounting side of the electrical housing,
wherein two of the contact tails are press-fit tails and one of the contact tails is a surface mount contact tail.

31. A midplane circuit board for forming an orthogonal interconnection between two daughtercards, said midplane circuit board comprising:
a first mating surface having a first differential signal pair of electrically conductive vias and a first ground via disposed in a first direction;
a second mating surface having a second differential signal pair of electrically conductive vias and a second ground via disposed in a second direction that is generally orthogonal to said first direction;
a relatively large ground via disposed adjacent to at least one of said first and second differential signal pair of electrically conductive vias;
wherein said relatively large ground via defines an opening that is large relative to said first and second ground vias; and
a trace electrically connecting said relatively large ground via to at least one of said first and second ground vias.

32. A circuit board having one or more giant ground holes, said circuit board comprising:
a giant ground via disposed adjacent to at least one of a first and second differential signal pair of electrically conductive vias;
wherein said giant ground via defines an opening that is large relative to said first and second ground vias.

33. The midplane circuit board of claim 32, further comprising:
a first ground via disposed adjacent to said first differential signal pair of electrically conductive vias along a first direction; and
a second ground via disposed adjacent to said second differential signal pair of electrically conductive vias along a second direction that is generally orthogonal to said first direction;
wherein said first ground via, said second ground via, and said giant ground via are electrically connected to one another.

34. A midplane circuit board for forming an orthogonal interconnection between two daughtercards, said midplane circuit board comprising:
a first mating surface having a first differential signal pair of electrically conductive pads disposed in a first direction;
a second mating surface having a second differential signal pair of electrically conductive pads disposed in a second direction that is generally orthogonal to said first direction;
at least one relatively small signal via disposed adjacent to at least one of said first and second differential signal pair of electrically conductive pads;
wherein said relatively small signal via is small in size relative to said first and second differential signal pair of electrically conductive pads;
wherein said relatively small signal via is electrically connected to at least one of said first and second differential signal pair of electrically conductive pads.

35. The midplane circuit board of claim 34, further comprising:
a first trace on said first mating surface that electrically connects one of said first plurality of electrically conductive pads to said relatively small signal via; and
a second trace on said second mating surface that electrically connects one of said second plurality of electrically conductive pads to said relatively small signal via;
wherein said relatively small signal via allows differential signals to pass from said first mating surface to said second mating surface through said relatively small signal via.
